(19) United States
(12) Patent Application Publication
(10) Pub. No.: US 2025/0040241 A1
(43) Pub. Date: Jan. 30, 2025

(54) SEMICONDUCTOR DEVICE AND METHOD FOR FABRICATING THE SAME

(71) Applicant: Samsung Electronics Co., Ltd., Suwon-si (KR)

(72) Inventors: Sung Il PARK, Suwon-si (KR); Jae Hyun PARK, Suwon-si (KR); Jin Wook YANG, Suwon-si (KR)

(73) Assignee: Samsung Electronics Co., Ltd., Suwon-si (KR)

(21) Appl. No.: 18/430,457

(22) Filed: Feb. 1, 2024

(30) Foreign Application Priority Data
Jul. 24, 2023 (KR) 10-2023-0096219

(51) Int. Cl. H01L 27/092; H01L 21/822; H01L 21/8238; H01L 29/06; H01L 29/417; H01L 29/423; H01L 29/66; H01L 29/775

(52) U.S. Cl. CPC H01L 27/0922; H01L 21/8221; H01L 21/823807; H01L 21/823814; H01L 21/823871; H01L 29/0673; H01L 29/41733; H01L 29/42392; H01L 29/66439; H01L 29/66545; H01L 29/775

(57) ABSTRACT

A semiconductor device includes a first active pattern extending in a first direction, a second active pattern on the first active pattern and extending in the first direction, a gate structure on the first active pattern and the second active pattern and extending in a second direction intersecting the first direction, a first source/drain region on side faces of the gate structure and connected to the first active pattern, a second source/drain region on the side faces of the gate structure and connected to the second active pattern, and an intermediate connecting layer which includes a first intermediate conductive pattern between the first active pattern and the second active pattern, and a second intermediate conductive pattern connected to the first intermediate conductive pattern between the first source/drain region and the second source/drain region.

### CROSS-REFERENCE TO RELATED APPLICATION

This application claims priority from Korean Patent Application No. 10-2023-0096219 filed on Jul. 24, 2023 in the Korean Intellectual Property Office, and all the benefits accruing therefrom under 35 U.S.C. 119, the contents of which in its entirety are herein incorporated by reference.

### BACKGROUND

Various example embodiments relate to a semiconductor device and/or a method for fabricating the same. More specifically, various example embodiments relate to a semiconductor device including stacked a multi-gate transistor and/or a method for fabricating the same.

As one of scaling technologies for increasing density of an integrated circuit device, a multi-gate transistor in which a fin-shaped or nanowire-shaped silicon body is formed on a substrate and a gate is formed on a surface of the silicon body has been proposed.

Since such a multi-gate transistor utilizes a three-dimensional channel, scaling may be more easily performed. Additionally or alternatively, even if a gate length of the multi-gate transistor is not increased, the current control capability may be improved. Additionally or alternatively, a SCE (short channel effect) in which potential of a channel region is influenced by a drain voltage may be more effectively suppressed or reduced.

### SUMMARY

Various example embodiments provide a semiconductor device having improved integration and/or performance.

Alternatively or additionally, various example embodiments provide a method for fabricating a semiconductor device capable of having improved integration and performance.

However, aspects of inventive concepts are not restricted to the one set forth herein. The above and other aspects features will become more apparent to one of ordinary skill in the art to which inventive concepts pertains by referencing the detailed description of various example embodiments given below.

According to some example embodiments, there is provided a semiconductor device comprising a first active pattern extending in a first direction, a second active pattern on the first active pattern and extending in the first direction, a gate structure on the first active pattern and the second active pattern and extending in a second direction intersecting the first direction, a first source/drain region on side faces of the gate structure and connected to the first active pattern, a second source/drain region on the side faces of the gate structure and connected to the second active pattern, and an intermediate connecting layer which includes a first intermediate conductive pattern between the first active pattern and the second active pattern, and a second intermediate conductive pattern connected to the first intermediate conductive pattern between the first source/drain region and the second source/drain region.

Additionally or alternatively, according to various example embodiments, there is provided a semiconductor device comprising a first active pattern extending in a first direction, a second active pattern on the first active pattern and extending in the first direction, a gate structure on the first active pattern and the second active pattern and extending in a second direction intersecting the first direction, a first source/drain region on side faces of the gate structure and connected to the first active pattern, a second source/drain region on side faces of the gate structure and connected to the second active pattern, an intermediate connecting layer interposed between the first active pattern and the second active pattern, and between the first source/drain region and the second source/drain region, a first source/drain contact which connects the first source/drain region and the intermediate connecting layer, and a second source/drain contact which connects the second source/drain region and the intermediate connecting layer.

Alternatively or additionally according to some example embodiments, there is provided a semiconductor device comprising a first active pattern extending in a first direction, a second active pattern on the first active pattern and extending in the first direction, a gate structure on the first active pattern and the second active pattern and extending in a second direction intersecting the first direction, a first source/drain region on side faces of the gate structure and connected to the first active pattern, a second source/drain region on side faces of the gate structure and connected to the second active pattern, an intermediate connecting layer extending in the first direction between the first active pattern and the second active pattern, and between the first source/drain region and the second source/drain region, a first insulating pattern interposed between the first active pattern and the intermediate connecting layer, a second insulating pattern interposed between the second active pattern and the intermediate connecting layer, a first intermediate insulating layer interposed between the first source/drain region and the intermediate connecting layer, and a second intermediate insulating layer interposed between the second source/drain region and the intermediate connecting layer.

### BRIEF DESCRIPTION OF DRAWINGS

The above and other aspects and/or features of inventive concepts will become more apparent by describing in detail illustrative embodiments thereof with reference to the attached drawings, in which:

FIG. 1 is an example circuit diagram for explaining a semiconductor device according to some example embodiments;

FIG. 2 is an example layout diagram for explaining the semiconductor device according to some example embodiments;

FIG. 3 is a cross-sectional view taken along line A-A of FIG. 2;

FIG. 4 is an enlarged view for explaining a region R of FIG. 3;

FIG. 5 is a cross-sectional view taken along line B-B of FIG. 2;

FIG. 6 is a cross-sectional view for explaining a semiconductor device according to some example embodiments;

FIG. 7 is an example layout diagram for explaining a semiconductor device according to some example embodiments;

FIG. 8 is a cross-sectional view taken along line A-A of FIG. 7;

FIG. 9 is an example circuit diagram for explaining a semiconductor device according to some example embodiments;

FIG. 10 is an example layout diagram for explaining the semiconductor device according to some example embodiments;

FIG. 11 is a cross-sectional view taken along line C-C of FIG. 10;

FIG. 12 is a cross-sectional view taken along line D-D of FIG. 10;

FIGS. 13 and 14 are various cross-sectional views for explaining a semiconductor device according to some example embodiments; and

FIGS. 15 to 52 are intermediate step diagrams for explaining the method for fabricating the semiconductor device according to some example embodiments.

### DETAILED DESCRIPTION OF VARIOUS EXAMPLE EMBODIMENTS

Herein, spatially relative terms “below”, “beneath”, “lower”, “above”, “upper”, and the like may be used to readily describe an interrelationship between one element or components and another element or components as shown in the drawings. The spatially relative terms should be understood as terms including different directions of the elements at the time of use or operation, in addition to a direction shown in the drawings. For example, if the element shown in the drawings is turned over, an element described as “below” or “beneath” the other element may be disposed “above” the other element. Thus, the example term “below” may include both below and above directions. The elements may be oriented in other directions, and thus, the spatially relative terms may be interpreted according to orientation.

Although terms such as first and second are used to describe various elements or components in the present specification, these elements or components are not limited by these terms. These terms are only used to distinguish a single element or component from other elements or components. Therefore, a first element or component referred to below may be or may correspond to a second element or component within the technical idea of the present disclosure.

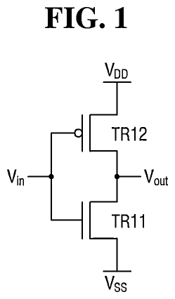

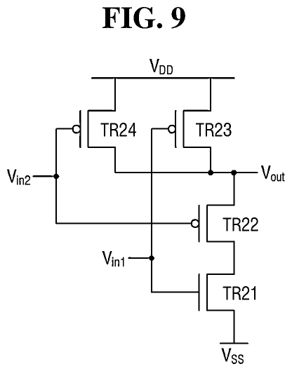

Hereinafter, a semiconductor device according to various example embodiments will be described with reference to FIGS. 1 to 12. Example embodiments with reference to FIGS. 1 to 8 will mainly be described with an inverter as a semiconductor device, and example embodiments disclosed with reference to FIGS. 9 to 12 will be mainly described with a NAND gate as a semiconductor device. However, these are just examples. Those of ordinary skill in the art will appreciate that the technical ideas of inventive concepts may be applied to various other logic elements such as an AND gate, an OR gate, a NOR gate, an AOI gate, a multiplexer (MUX) gate, a decoder (DEC) gate, an XOR gate, and/or various other semiconductor devices such as but not limited to a SRAM (static random access memory) element and/or a latch such as a flip-flop.

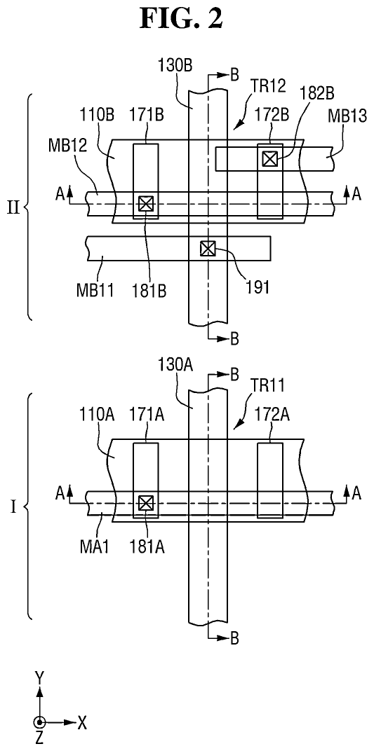

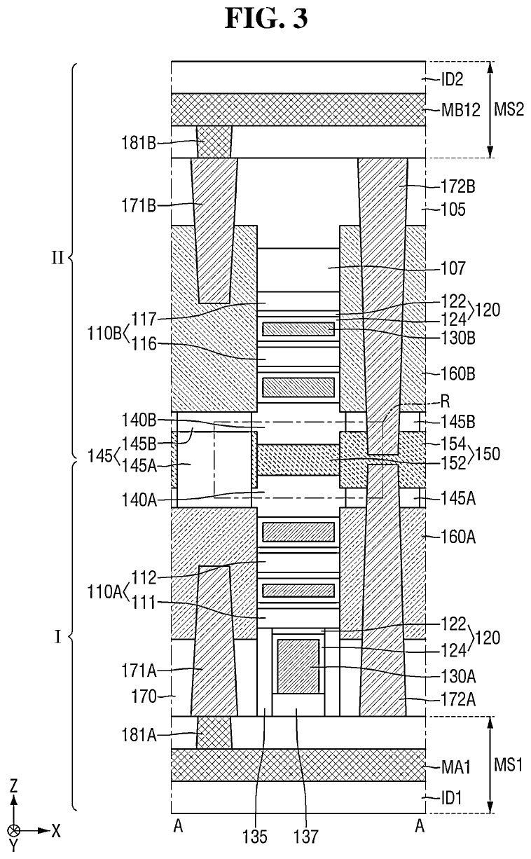

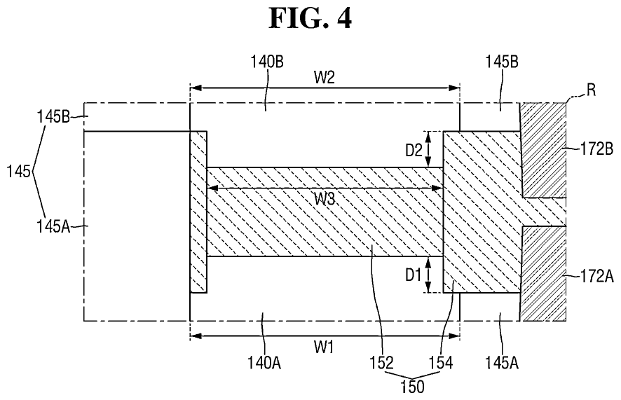

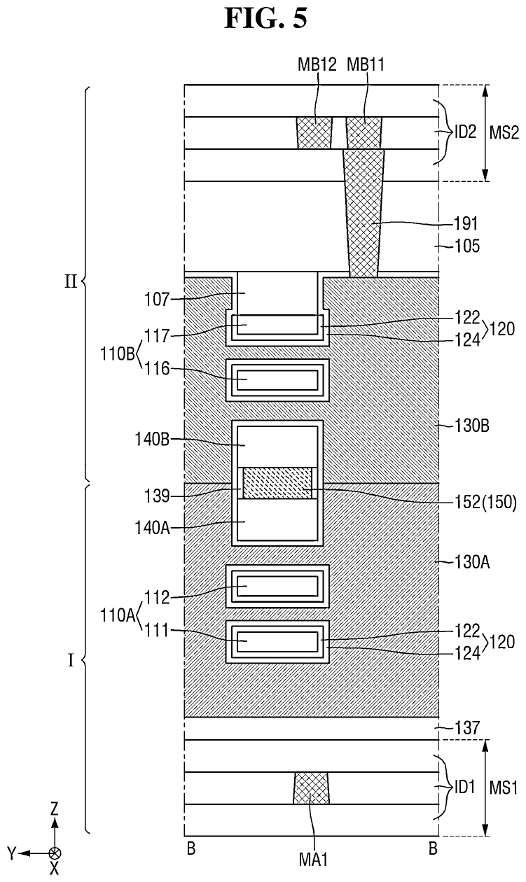

FIG. 1 is an example circuit diagram for explaining a semiconductor device according to some example embodiments. FIG. 2 is an example layout diagram for explaining the semiconductor device according to some example embodiments. FIG. 3 is a cross-sectional view taken along line A-A of FIG. 2. FIG. 4 is an enlarged view for explaining a region R of FIG. 3. FIG. 5 is a cross-sectional view taken along line B-B of FIG. 2.

Referring to FIG. 1, a semiconductor device according to some example embodiments may be provided as an inverter circuit.

For example, the semiconductor device according to some example embodiments may include a first transistor TR11 and a second transistor TR12 connected in series between a ground node V_{SS} and a power supply node V_{DD}. The first transistor TR11 may be or may correspond to an NFET and the second transistor TR12 may be or may correspond to a PFET. A source of the first transistor TR11 may be connected to the ground node V_{SS}, and a source of the second transistor TR12 may be connected to the power supply node V_{DD}. An input signal Vᵢₙ of an inverter may be input to a gate of the first transistor TR11 and a gate of the second transistor TR12. An output signal Vₒᵤₜ of the inverter may be output from a node to which a drain of the first transistor TR11 and a drain of the second transistor TR12 are connected.

Referring to FIGS. 1 to 5, the semiconductor device according to various example embodiments may include a first region I and a second region II.

The first region I and the second region II may be stacked sequentially. For example, the second region II may be above the first region I. The following description will be mainly provided as a case where the first transistor TR11 is provided in the first region I and the second transistor TR12 is provided in the second region II. However, this is only an example, and in some example embodiments the second transistor TR12 may be provided in the first region I and the first transistor TR11 may be provided in the second region II

The semiconductor device according to some example embodiments may include a first active pattern 110A, a second active pattern 110B, first gate structures 130A and 130B, a first gate dielectric film 120, a first gate spacer 135, a first gate capping pattern 137, a first source/drain region 160A, a second source/drain region 160B, an intermediate connecting layer 150, a first insulating pattern 140A, a second insulating pattern 140B, an intermediate spacer 139, an intermediate isolation layer 145, first source/drain contacts 171A and 172A, second source/drain contacts 171B and 172B, a first wiring structure MS1, and a second wiring structure MS2.

The first active pattern 110A may be disposed in the first region I, and the second active pattern 110B may be disposed in the second region II. The first active pattern 110A and the second active pattern 110B may be sequentially stacked, e.g., vertically stacked. The first active pattern 110A and the second active pattern 110B may be spaced apart from each other, and extend long in the first direction X, respectively.

In some example embodiments, the first active pattern 110A may include a plurality of lower bridge patterns (e.g., first and second lower bridge patterns 111 and 112) stacked in sequence and spaced from one another. In some example embodiments, the second active pattern 110B may include a plurality of upper bridge patterns (e.g., first and second upper bridge patterns 116 and 117) that are stacked in sequence and spaced from each other. Such first active pattern 110A and second active pattern 110B may be used as channel region of a multi-bridge channel field effect transistor (MBCFET®) each including a multi-bridge channel. The number of bridge patterns included in each of first active pattern 110A and second active pattern 110B is merely an example, and is not limited to the shown example.

The first active pattern 110A and the second active pattern 110B may each include silicon (Si) and/or germanium (Ge) which are elemental semiconductor materials. Alternatively or additionally, the first active pattern 110A and the second active pattern 110B may each include a compound semiconductor, for example, a group IV-IV compound semiconductor or a group III-V compound semiconductor. The group IV-IV compound semiconductor may include, for example, a binary compound or a ternary compound including at least two or more of carbon (C), silicon (Si), germanium (Ge), and tin (Sn), or a compound obtained by doping these elements with a group IV element. The group III-V compound semiconductor may be, for example, at least one of a binary compound, a ternary compound or a quaternary compound formed by combining at least one of aluminum (Al), gallium (Ga) and indium (In) as a group III element with one of phosphorus (P), arsenic (As) and antimony (Sb) as a group V element.

In some example embodiments, the second active pattern 110B and the first active pattern 110A may be sequentially stacked on the insulating substrate 105. The insulating substrate 105 may include, for example, but not limited to, at least one of silicon oxide, silicon oxynitride, silicon oxycarbonitride, and combinations thereof. As an example, the insulating substrate 105 may include a silicon oxide film. In some example embodiments, the insulating substrate 105 may not include silicon nitride; however, example embodiments are not limited thereto.

In some example embodiments, a base insulating pattern 107 may be formed on the insulating substrate 105. The base insulating pattern 107 may be interposed between the insulating substrate 105 and the second active pattern 110B. The base insulating substrate 107 may include, for example, but not limited to, at least one of silicon oxide, silicon oxynitride, silicon oxycarbonitride, and combinations thereof. For example, the base insulating pattern 107 may include a silicon nitride film. In some example embodiments, the base insulating pattern 107 may not include silicon oxide; however, example embodiments are not limited thereto.

The first gate structures 130A and 130B may intersect the first active pattern 110A and the second active pattern 110B. For example, the first gate structures 130A and 130B may extend long in a second direction Y intersecting the first direction X. The first gate structures 130A and 130B may surround the periphery of the first active pattern 110A and the periphery of the second active pattern 110B. For example, the first active pattern 110A and the second active pattern 110B may extend in the first direction X and penetrate the first gate structures 130A and 130B.

In some example embodiments, the first gate structures 130A and 130B may include a first lower gate electrode 130A intersecting the first active pattern 110A, and a first upper gate electrode 130B intersecting the second active pattern 110B. The first active pattern 110A may extend in the first direction X to penetrate the first lower gate electrode 130A, and the second active pattern 110B may extend in the first direction X to penetrate the first upper gate electrode 130B.

The first lower gate electrode 130A and the first upper gate electrode 130B may each include a conductive material, for example, but not limited to at least one of TiN, WN, TaN, Ru, TiC, TaC, Ti, Ag, Al, TiAl, TiAlN, TiAlC, TaCN, TaSiN, Mn, Zr, W, Al and combinations thereof. Alternatively or additionally, each of the first lower gate electrode 130A and the first upper gate electrode 130B may be formed by, but not limited to, a replacement process.

Although each of the first lower gate electrode 130A and the first upper gate electrode 130B is only shown as a single film, this is merely an example, and they may be formed by stacking a plurality of conductive films. For example, each of the first lower gate electrode 130A and the first upper gate electrode 130B may include a work function adjusting film that adjusts the work function, and a filling conductive film that fills a space formed by the work function adjusting film. The work function adjusting film may include, for example, at least one of TIN, TaN, TiC, TaC, TiAlC, and combinations thereof. The filling conductive film may include, for example, W or Al.

In some example embodiments, the first lower gate electrode 130A and the first upper gate electrode 130B may include different conductive materials from each other, and in some example embodiments may not include a common material. For example, the first lower gate electrode 130A and the first upper gate electrode 130B may include work function adjusting films of different conductivity types from each other. As an example, the first lower gate electrode 130A may include an n-type work function adjusting film and in some example embodiments may not include a p-type work function adjusting film, and the first upper gate electrode 130B may include a p-type work function adjusting film and in some example embodiments may not include an n-type work adjusting film. In some example embodiments, the first lower gate electrode 130A and the first upper gate electrode 130B may include the same conductive material as each other.

The first gate dielectric film 120 may be interposed between the first active pattern 110A and the first lower gate electrode 130A, and between the second active pattern 110B and the first upper gate electrode 130B. The first gate dielectric film 120 may include a dielectric material, for example, at least one of silicon oxide, silicon oxynitride, silicon nitride or a high dielectric constant material having a higher dielectric constant than silicon oxide. The high dielectric constant material may include, for example, but not limited to, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate or combinations thereof.

The first gate spacers 135 may extend along the side faces of the first gate structures 130A and 130B. Each of the first active pattern 110A and the second active pattern 110B may extend in the first direction X and penetrate the first gate spacer 135. The first gate spacer 135 may include an insulating material, for example, but not limited to, at least one of silicon oxide, silicon nitride, silicon oxynitride, silicon oxycarbide, silicon boron nitride, silicon boron carbonitride, silicon oxycarbonitride, and combinations thereof.

In some example embodiments, the first gate dielectric film 120 includes a first interfacial film 122 and a first high dielectric film 124 that are sequentially stacked on the first active pattern 110A and the second active pattern 110B.

The first interfacial film 122 may surround each of the bridge patterns 111, 112, 116 and 117. For example, the first interfacial film 122 may extend conformally along the periphery of each of the bridge patterns 111, 112, 116 and 117.

In some example embodiments, the first interfacial film 122 may include an oxide film formed by oxidizing (e.g., thermally oxidizing) the surfaces of the bridge patterns 111, 112, 116, and 117. As an example, when the first active pattern 110A and the second active pattern 110B each include silicon (Si), the first interfacial film 122 may include a silicon oxide film.

The first high dielectric film 124 may surround the periphery of the first interfacial film 122. Also, a part of the first high dielectric film 124 may be interposed between the first gate structures 130A and 130B and the first gate spacers 135. For example, the first high dielectric film 124 may conformally extend along the periphery of the first interfacial film 122 and the profile of the inner side face of the first gate spacer 135. In some example embodiments, the first high dielectric film 124 may further extend along the side faces of the base insulating pattern 107 and the upper surface of the insulating substrate 105.

The first high dielectric film 124 may include a high dielectric constant material having a higher dielectric constant than silicon oxide. The high dielectric constant material may include, for example, but not limited to, at least one of hafnium oxide (HfO₂), zirconium oxide (ZrO₂), lanthanum oxide (La₂O₃), aluminum oxide (Al₂O₃), titanium oxide (TiO₂), strontium titanium oxide (SrTiO₃), lanthanum aluminum oxide (LaAlO₃), yttrium oxide (Y₂O₃), hafnium oxynitride (HfOₓN_{y}), zirconium oxynitride (ZrOₓN_{y}), lanthanum oxynitride (La₂OₓN_{y}), aluminum oxynitride (Al₂OₓN_{y}), titanium oxynitride (TiOₓN_{y}), strontium titanium oxynitride (SrTiOₓN_{y}), lanthanum aluminum oxynitride (LaAlOₓN_{y}), yttrium oxynitride (Y₂OₓN_{y}), and combinations thereof.

The first gate capping pattern 137 may extend along the lower surfaces of the first gate structures 130A and 130B. The first gate capping pattern 137 may include an insulating material, for example, but not limited to, at least one of silicon oxide, silicon nitride, silicon oxynitride, silicon oxycarbide, silicon boron nitride, silicon boron carbonitride, silicon oxycarbonitride, and combinations thereof.

A first source/drain region 160A may be disposed in the first region I. The first source/drain regions 160A may be formed on the side faces of the first lower gate electrode 130A. The first active pattern 110A penetrates the first lower gate electrode 130A and the first gate spacers 135, and may be connected to the first source/drain region 160A. The first source/drain region 160A may be electrically isolated from the first lower gate electrode 130A by the first gate spacer 135.

In some example embodiments, the first source/drain region 160A may include an epitaxial layer doped with impurities. For example, the first source/drain region 160A may include an epitaxial layer such as a homogenous epitaxial layer grown from the first active pattern 110A by an epitaxial growth method.

The second source/drain region 160B may be disposed in the second region II. The second source/drain region 160B may be formed on the side faces of the first upper gate electrode 130B. The second active pattern 110B penetrates the first upper gate electrode 130B and the first gate spacers 135, and may be connected to the second source/drain region 160B. The second source/drain region 160B may be electrically isolated from the first upper gate electrode 130B by the first gate spacer 135.

In some example embodiments, the second source/drain region 160B may include an epitaxial layer doped with impurities. For example, the second source/drain region 160B may include an epitaxial layer such as a homogenous epitaxial layer grown from the second active pattern 110B by an epitaxial growth method.

In some example embodiments, the first source/drain region 160A and the second source/drain region 160B may have different conductivity types from each other. As an example, the first source/drain region 160A may include n-type impurities, and the second source/drain region 160B may include p-type impurities. In such a case, the first active pattern 110A may be used as the channel region of NFET, and the second active pattern 110B may be used as the channel region of PFET.

In some example embodiments, either or both of the first source/drain region 160A and the second source/drain region 160B may include counterdopants, e.g., counterdopants at a low concentration. For example, in some example embodiments, the first source/drain region 160A may include n-type impurities at a high concentration and p-type impurities at a low, e.g., much lower concentration. Alternatively or additionally in some example embodiments, the second source/drain region 160 B may include p-type impurities at a high concentration and n-type impurities at a low, e.g., much lower concentration.

In some example embodiments, an interlayer insulating film 170 that fills a space on the lower surface of the second source/drain regions 160B and the outer side face of the first gate spacer 135 may be formed. The interlayer insulating film 170 may include, for example, but not limited to, at least one of silicon oxide, silicon nitride, silicon oxynitride, silicon oxycarbide, silicon boron nitride, silicon boron carbonitride, silicon oxycarbonitride, and a low dielectric constant material having a lower dielectric constant than silicon oxide.

The intermediate connecting layer 150 may be interposed between the first active pattern 110A and the second active pattern 110B, and between the first source/drain region 160A and the second source/drain region 160B. The intermediate connecting layer 150 may be spaced apart from the first active pattern 110A, the second active pattern 110B, the first source/drain region 160A, and the second source/drain region 160B. The intermediate connecting layer 150 may extend in the first direction X. The intermediate connecting layer 150 may include, but not limited to, a conductive material, for example, at least one of polysilicon, TiN, TiSiN, tungsten, tungsten silicide, and combinations thereof.

The intermediate connecting layer 150 may include a first intermediate conductive pattern 152 and a second intermediate conductive pattern 154. The first intermediate conductive pattern 152 may be interposed between the first active pattern 110A and the second active pattern 110B. The second intermediate conductive pattern 154 may be interposed between the first source/drain region 160A and the second source/drain region 160B. Although only an example in which a boundary, e.g., an interface, exists between the first intermediate conductive pattern 152 and the second intermediate conductive pattern 154 is shown, this is only an example. Depending on the features of the process for forming the intermediate connecting layer 150, the boundary between first intermediate conductive pattern 152 and second intermediate conductive pattern 154 may not exist.

In some example embodiments, the first intermediate conductive pattern 152 and the second intermediate conductive pattern 154 may each include an epitaxial layer that is doped with impurities independently. The impurities may include, for example, but not limited to, p-type impurities (e.g., one or more of boron (B), indium (In), gallium (Ga), and aluminum (Al)) or n-type impurities (e.g., one or more of phosphorus (P), arsenic (As) or antimony (Sb)). As an example, the first intermediate conductive pattern 152 and the second intermediate conductive pattern 154 may each include a silicon (Si) epitaxial layer doped with boron (B), a silicon germanium (SiGe) epitaxial layer doped with boron (B) or a silicon (Si) epitaxial layer doped with phosphorus (P) independently.

In some example embodiments, the second intermediate conductive pattern 154 may include an epitaxial layer grown from the first intermediate conductive pattern 152 by the epitaxial growth method.

In some example embodiments, the lower surface of the first intermediate conductive pattern 152 may have a step with the lower surface of the second intermediate conductive pattern 154. In some example embodiments, the lower surface of the second intermediate conductive pattern 154 may protrude below the lower surface of the first intermediate conductive pattern 152 (e.g., toward the first active pattern 110A). For example, as shown in FIG. 4, the lower surface of the second intermediate conductive pattern 154 may be formed to be lower than the lower surface of the first intermediate conductive pattern 152 by D1.

In some example embodiments, the upper surface of the first intermediate conductive pattern 152 may have a step with the upper surface of the second intermediate conductive pattern 154. In some example embodiments, the upper surface of the second intermediate conductive pattern 154 may protrude above the upper surface of the first intermediate conductive pattern 152 (e.g., toward the second active pattern 110B). For example, as shown in FIG. 4, the upper surface of the second intermediate conductive pattern 154 may be formed to be higher than the upper surface of the first intermediate conductive pattern 152 by D2.

The first insulating pattern 140A may be interposed between the first active pattern 110A and the intermediate connecting layer 150. For example, the first insulating pattern 140A may be interposed between the first active pattern 110A and the first intermediate conductive pattern 152. The intermediate connecting layer 150 may be spaced apart from the first active pattern 110A by the first insulating pattern 140A. The first insulating pattern 140A may electrically isolate the first active pattern 110A and the intermediate connecting layer 150.

The second insulating pattern 140B may be interposed between the second active pattern 110B and the intermediate connecting layer 150. For example, the second insulating pattern 140B may be interposed between the second active pattern 110B and the first intermediate conductive pattern 152. The intermediate connecting layer 150 may be spaced apart from the second active pattern 110B by the second insulating pattern 140B. The second insulating pattern 140B may electrically isolate the second active pattern 110B and the intermediate connecting layer 150.

In some example embodiments, a first width W1 of the first insulating pattern 140A and a second width W2 of the second insulating pattern 140B may be greater than a third width W3 of the first intermediate conductive pattern 152. As shown in FIG. 4, each of the first width W1, the second width W2, and the third width W3 corresponds to a width in the first direction X.

In some example embodiments, a part of the first insulating pattern 140A may protrude beyond the side face of the first lower gate electrode 130A and/or the side face of the first active pattern 110A, and extend along a part of the upper surface of the first source/drain region 160A. For example, a part of the first insulating pattern 140A may overlap a part of the first source/drain region 160A in a third direction Z. For example, a lower part of the first insulating pattern 140A may include a first recess extending from the side face of the first lower gate electrode 130A. A part of the first source/drain region 160A may fill the first recess.

In some example embodiments, a part of the first insulating pattern 140A protrudes from the side face of the first intermediate conductive pattern 152 intersecting the first direction X, and may extend along a part of the lower surface of the second intermediate conductive pattern 154. For example, a part of the first insulating pattern 140A may overlap a part of the second intermediate conductive pattern 154 in the third direction Z. For example, the upper part of the first insulating pattern 140A may include a second recess extending from the side face of the first intermediate conductive pattern 152 intersecting the first direction X. A part of the second intermediate conductive pattern 154 may fill the second recess.

In some example embodiments, a part of the second insulating pattern 140B protrudes beyond the side face of the first intermediate conductive pattern 152 intersecting the first direction X, and may extend along a part of the upper surface of the second intermediate conductive pattern 154. For example, a part of the second insulating pattern 140B may overlap a part of the second intermediate conductive pattern 154 in the third direction Z. For example, the lower part of the second insulating pattern 140B may include a third recess extending from the side face of the first intermediate conductive pattern 152 intersecting the first direction X. A part of the second intermediate conductive pattern 154 may fill the third recess.

In some example embodiments, a part of the second insulating pattern 140B protrudes beyond the side face of the first upper gate electrode 130B and/or the side face of the second active pattern 110B, and may extend along a part of the lower surface of the second source/drain regions 160B. For example, a part of the second insulating pattern 140B may overlap a part of the second source/drain region 160B in the third direction Z. For example, the upper part of the second insulating pattern 140B may include a fourth recess extending from the side face of the first upper gate electrode 130B. A part of the second source/drain region 160B may fill the fourth recess.

In some example embodiments, the first insulating pattern 140A, the intermediate connecting layer 150, and the second insulating pattern 140B may be disposed inside the first gate structures 130A and 130B between the first active pattern 110A and the second active pattern 110B. For example, a part of the first gate structures 130A and 130B may be interposed between the first active pattern 110A and the first insulating pattern 140A, and between the second active pattern 110B and the second insulating pattern 140B. The first gate dielectric film 120 may be interposed between the first insulating pattern 140A and the first gate structures 130A and 130B, between the intermediate connecting layer 150 and the first gate structures 130A and 130B, and between the second insulating pattern 140B and the first gate structures 130A and 130B. For example, as shown in FIG. 5, a part of the first high dielectric film 124 may surround the periphery of the first insulating pattern 140A, the intermediate connecting layer 150, and the second insulating pattern 140B.

The first insulating pattern 140A and the second insulating pattern 140B may each independently or concurrently include, for example, but not limited to, at least one of silicon oxide, silicon nitride, silicon oxynitride, silicon oxycarbide, silicon boron nitride, silicon boron carbonitride, silicon oxycarbonitride, and combinations thereof. As an example, the first insulating pattern 140A and the second insulating pattern 140B may each include a silicon nitride film.

In some example embodiments, the first insulating pattern 140A and the second insulating pattern 140B may be formed at the same level. In this specification, “same level” means formed by the same fabricating process. For example, the first insulating pattern 140A and the second insulating pattern 140B may include the same silicon nitride film.

In some example embodiments, the first insulating pattern 140A and the second insulating pattern 140B may be formed at the same level as the base insulating pattern 107. As an example, the base insulating pattern 107, the first insulating pattern 140A and the second insulating pattern 140B may include the same silicon nitride film as each other. However, example embodiments are not limited thereto. For example, the first insulating pattern 140A and the second insulating pattern 140B may or may not include the same material; example embodiments are not limited thereto.

The intermediate isolation layer 145 may be interposed between the first source/drain region 160A and the second source/drain region 160B. The intermediate connecting layer 150 may be spaced apart from the first source/drain region 160A and the second source/drain region 160B by the intermediate isolation layer 145. The intermediate isolation layer 145 may electrically isolate the intermediate connecting layer 150, the first source/drain region 160A, and the second source/drain region 160B from each other.

The intermediate isolation layer 145 may include an insulating material, for example, but not limited to, at least one of silicon oxide, silicon nitride, silicon oxynitride, silicon oxycarbide, silicon boron nitride, silicon boron carbonitride, silicon oxycarbonitride, and combinations thereof. As an example, the intermediate isolation layer 145 may include a silicon oxide film.

In some example embodiments, the intermediate isolation layer 145 may include a first intermediate insulating layer 145A and a second intermediate insulating layer 145B. The first intermediate insulating layer 145A may be interposed between the first source/drain region 160A and the intermediate connecting layer 150. For example, the first intermediate insulating layer 145A may be interposed between the first source/drain region 160A and the second intermediate conductive pattern 154. The second intermediate insulating layer 145B may be interposed between the second source/drain region 160B and the intermediate connecting layer 150. For example, the second intermediate insulating layer 145B may be interposed between the second source/drain region 160B and the second intermediate conductive pattern 154.

In some example embodiments, a part of the intermediate isolation layer 145 may cut a part of the second intermediate conductive pattern 154. For example, as shown in FIG. 3, a first portion of the first intermediate insulating layer 145A disposed on one side of the first intermediate conductive pattern 152 may extend in the third direction Z to cut the second intermediate conductive pattern 154, and a second portion of the first intermediate insulating layer 145A disposed on the other side of the first intermediate conductive pattern 152 may extend along the lower surface of the second intermediate conductive pattern 154. The first portion of the first intermediate insulating layer 145A penetrates the second intermediate conductive pattern 154 and may be in contact with the lower surface of the second intermediate insulating layer 145B. Although only an example in which a boundary, e.g., an interface, exists between the first intermediate insulating layer 145A and the second intermediate insulating layer 145B is shown, this is only an example. Depending on the features of the process for forming the intermediate isolation layer 145, the boundary between the first intermediate conductive pattern 152 and the second intermediate conductive pattern 154 may not exist.

The intermediate spacer 139 may be formed on a side face of the intermediate connecting layer 150 intersecting the second direction Y. For example, as shown in FIG. 5, the intermediate spacer 139 may extend along the side face of the intermediate connecting layer 150 that intersects the second direction Y.

The intermediate spacer 139 may include an insulating material, for example, but not limited to, at least one of silicon oxide, silicon nitride, silicon oxynitride, silicon oxycarbide, silicon boron nitride, silicon boron carbonitride, silicon oxycarbonitride, and combinations thereof. As an example, the intermediate spacer 139 may include a silicon nitride film.

In some example embodiments, the intermediate spacer 139 may be interposed between the first insulating pattern 140A and the second insulating pattern 140B. For example, the first insulating pattern 140A may cover the lower surface of the intermediate spacer 139, and the second insulating pattern 140B may cover the upper surface of the intermediate spacer 139.

The first source/drain contacts 171A and 172A may be disposed in the first region I. The first source/drain contacts 171A and 172A may each be connected to the first source/drain region 160A.

For example, a first lower source/drain contact 171A connected to the first source/drain region 160A on one side of the first gate structures 130A and 130B may be formed, and a second lower source/drain contact 172A connected to the first source/drain region 160A on the other side of the first gate structures 130A and 130B may be formed. In some example embodiments, each of the first source/drain contacts 171A and 172A may extend in the third direction Z and penetrate the interlayer insulating film 170.

In some example embodiments, the first source/drain region 160A connected to the first lower source/drain contact 171A may be electrically isolated from the intermediate connecting layer 150 by the intermediate isolation layer 145.

In some example embodiments, a second lower source/drain contact 172A may connect the first source/drain region 160A and the intermediate contact layer 150. For example, the second lower source/drain contact 172A may penetrate the first source/drain region 160A and be connected to the second intermediate conductive pattern 154.

The second source/drain contacts 171B and 172B may be disposed in the second region II. The second source/drain contacts 171B and 172B may each be connected to the second source/drain region 160B.

For example, a first upper source/drain contact 171B connected to the second source/drain region 160B on one side of the first gate structures 130A and 130B may be formed, and a second upper source/drain contact 172B connected to the second source/drain region 160B on the other side of the first gate structures 130A and 130B may be formed. In some example embodiments, each of the second source/drain contacts 171B and 172B may extend in the third direction Z to penetrate the insulating substrate 105.

In some example embodiments, the second source/drain region 160B connected to the first upper source/drain contact 171B may be electrically isolated from the intermediate connecting layer 150 by the intermediate isolation layer 145.

In some example embodiments, a second upper source/drain contact 172B may connect the second source/drain region 160B and the intermediate contact layer 150. For example, the second upper source/drain contact 172B may penetrate the first source/drain region 160A, and be connected to the second intermediate conductive pattern 154.

The second lower source/drain contact 172A and the second upper source/drain contact 172B may be electrically connected through the intermediate connecting layer 150. That is, the first source/drain region 160A connected to the second lower source/drain contact 172A and the second source/drain region 160B connected to the second upper source/drain contact 172B may be electrically connected.

The first wiring structure MS1 may be formed on the interlayer insulating film 170. The interlayer insulating film 170 may be interposed between the first source/drain region 160A and the first wiring structure MS1. The first wiring structure MS1 may include a first inter-wiring insulating film ID1, and lower wiring patterns MA1 inside the first inter-wiring insulating film ID1.

The second wiring structure MS2 may be formed on, e.g., on top of, the insulating substrate 105. The insulating substrate 105 may be interposed between the second source/drain region 160B and the second wiring structure MS2. The second wiring structure MS2 may include a second inter-wiring insulating film ID2, and upper wiring patterns MB11 to MB13 inside the second inter-wiring insulating film ID2. The upper wiring patterns MB11 to MB13 may be insulated from each other by the second inter-wiring insulating film ID2.

An input signal Vᵢₙ of an inverter may be provided to the first gate structures 130A and 130B (refer to FIG. 1). For example, a first gate contact 191 connected to the first gate structures 130A and 130B may be formed. Also, the second wiring structure MS2 may include a first upper wiring pattern MB11 connected to the first gate contact 191. The first upper wiring pattern MB11 may provide the input signal Vᵢₙ. The input signal Vᵢₙ of the first upper wiring pattern MB11 may be input to the gates (i.e., the first gate structures 130A and 130B) of the first transistor TR11 and the second transistor TR12 through the first gate contact 191. In some example embodiments, the first upper wiring pattern MB11 may extend long in the first direction X.

Although the wiring pattern that provides the input signal Vᵢₙ of the inverter is described as only being included in the second wiring structure MS2, this is merely an example. The wiring pattern that provides the input signal Vᵢₙ of the inverter may be included in the first wiring structure MS1.

The first lower source/drain contact 171A may be connected to the ground node V_{SS}. For example, a first lower contact via 181A connected to the first lower source/drain contact 171A may be formed. Also, the first wiring structure MS1 may include a first lower wiring pattern MA1 connected to the first lower contact via 181A. The first lower wiring pattern MA1 may be provided as the ground node V_{SS}. The ground node V_{SS} of the first lower wiring pattern MA1 may be connected to the source of the first transistor TR11 (for example, the first source drain/region 160A connected to the first lower source/drain contact 171A) through the first lower contact via 181A. In some example embodiments, the first lower wiring pattern MA1 may extend long in the first direction X.

The first upper source/drain contact 171B may be connected to the power supply node V_{DD}. For example, a first upper contact via 181B connected to the first upper source/drain contact 171B may be formed. Also, the second wiring structure MS2 may include a second upper wiring pattern MA12 connected to the first upper contact via 181B. The second upper wiring pattern MA12 may be provided as a power supply node V_{DD}. The power supply node V_{DD} of the second upper wiring pattern MA12 may be connected to the source of the second transistor TR12 (e.g., the second source drain/region 160B connected to the first upper source/drain contact 171B) through the first upper contact via 181B. In some example embodiments, the second upper wiring pattern MA12 may extend long in the first direction X.

The second wiring structure MS2 may include a third upper wiring pattern MA13 provided as the output signal Vₒᵤₜ of the inverter. For example, a second upper contact via 182B connected to the second upper source/drain contact 172B may be formed. The third upper wiring pattern MA13 may be connected to the drain of the first transistor TR11 (i.e., the first source/drain region 160A connected to the second lower source/drain contact 172A), and the drain of the second transistor TR12 (i.e., the second source/drain region 160B connected to the second upper source/drain contact 172B) through the second upper contact via 182B and the intermediate connecting layer 150.

Although the wiring pattern provided as the output signal Vₒᵤₜ of the inverter is described as only being included inside the second wiring structure MS2, this is merely an example. The wiring pattern provided as the output signal Vₒᵤₜ of the inverter may be included inside the first wiring structure MS1.

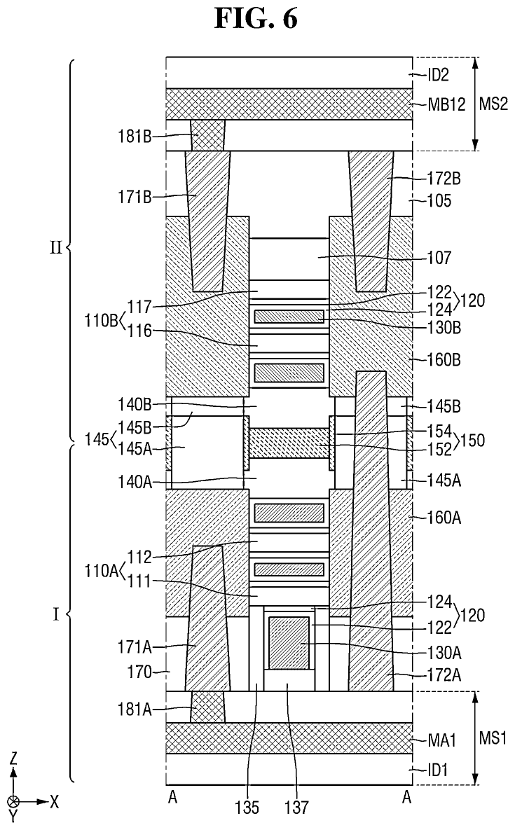

FIG. 6 is a cross-sectional view for explaining a semiconductor device according to some example embodiments. For convenience of explanation, repeated parts of contents explained above using FIGS. 1 to 5 will be briefly explained or omitted.

Referring to FIGS. 1, 2 and 6, in the semiconductor device according to some example embodiments, the second lower source/drain contact 172A may connect the first source/drain region 160A and the second source/drain region 160B.

For example, the second lower source/drain contact 172A may penetrate the first source/drain region 160A and the intermediate isolation layer 145, and be connected to the second source/drain region 160B. The intermediate isolation layer 145 may cut the second intermediate conductive pattern 154 in the region through which the second lower source/drain contact 172A penetrates. For example, the second portion of the first intermediate insulating layer 145A disposed on the other side of the first intermediate conductive pattern 152 may extend in the third direction Z to cut the second intermediate conductive pattern 154. Therefore, the second lower source/drain contact 172A may be electrically isolated from the intermediate connecting layer 150 by the intermediate isolation layer 145.

Although only an example in which the second lower source/drain contact 172A connects the first source/drain region 160A and the second source/drain region 160B, this is merely an example. The second upper source/drain contact 172B may connect the first source/drain region 160A and the second source/drain region 160B.

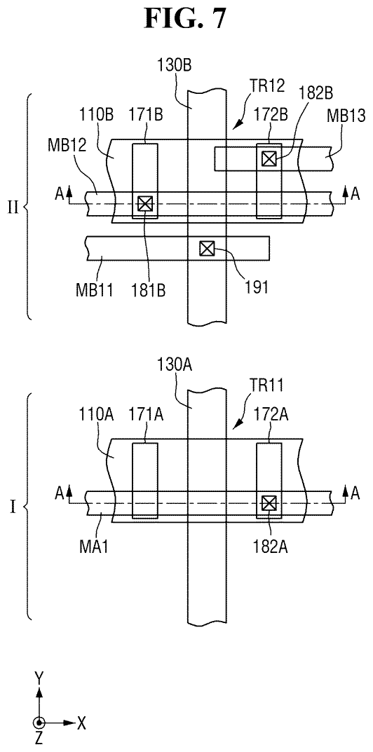

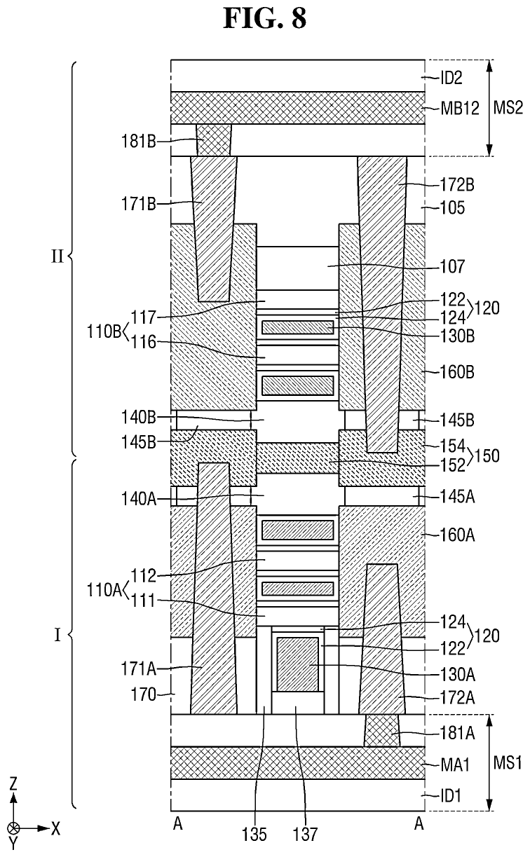

FIG. 7 is an example layout diagram for explaining a semiconductor device according to some example embodiments. FIG. 8 is a cross-sectional view taken along line A-A of FIG. 7. For convenience of explanation, repeated parts of contents explained above using FIGS. 1 to 6 will be briefly explained or omitted.

Referring to FIGS. 1, 7 and 8, in the semiconductor device according to some example embodiments, the first lower source/drain contact 171A and the second upper source/drain contact 172B may be electrically connected through the intermediate contact layer 150.

For example, the first lower source/drain contact 171A may penetrate the first source/drain region 160A, and be connected to the second intermediate conductive pattern 154. Thus, the first source/drain region 160A connected to the first lower source/drain contact 171A and the second source/drain region 160B connected to the second upper source/drain contact 172B may be electrically connected.

The first source/drain region 160A connected to the second lower source/drain contact 172A may be electrically isolated from the intermediate connecting layer 150 by the intermediate isolation layer 145.

The second lower source/drain contact 172A may be connected to the ground node V_{SS}. For example, a second lower contact via 182A that connects the second lower source/drain contact 172A and the first lower wiring pattern MA1 may be formed. The ground node V_{SS} of the first lower wiring pattern MA1 may be connected to the source of the first transistor TR11 (for example, the first source/drain region 160A connected to the second lower source/drain contact 172A) through the second lower contact via 182A.

The third upper wiring pattern MA13 may be connected to the drain of the first transistor TR11 (for example, the first source/drain region 160A connected to the first lower source/drain contact 171A), and the drain of the second transistor TR12 (e.g., the second source/drain region 160B connected to the second upper source/drain contact 172B) through the second upper contact via 182B and the intermediate connecting layer 150. Accordingly, the third upper wiring pattern MA13 may be provided as the output signal Vₒᵤₜ of the inverter (refer to FIG. 1).

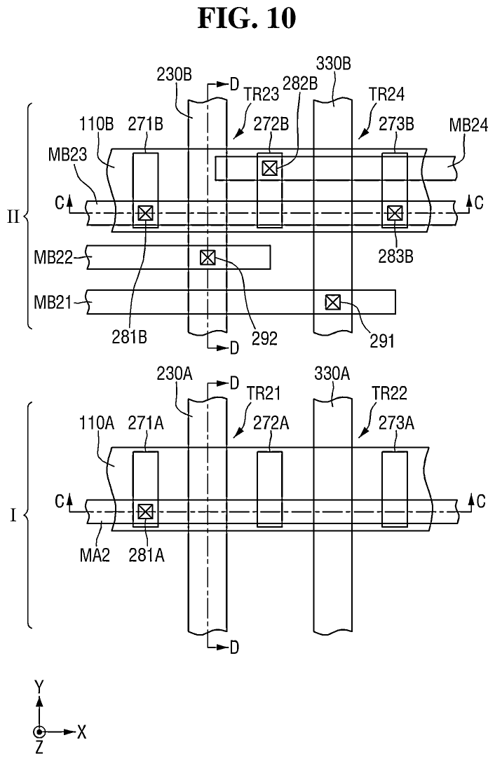

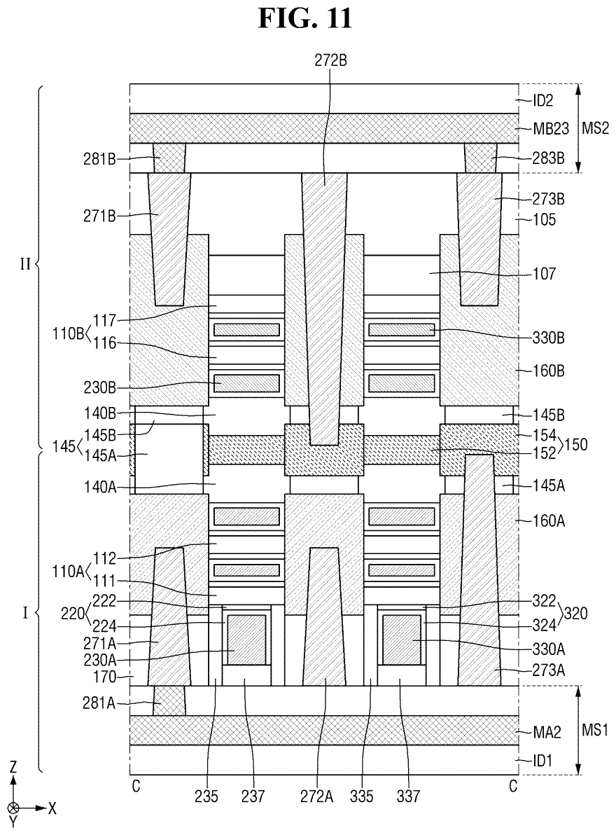

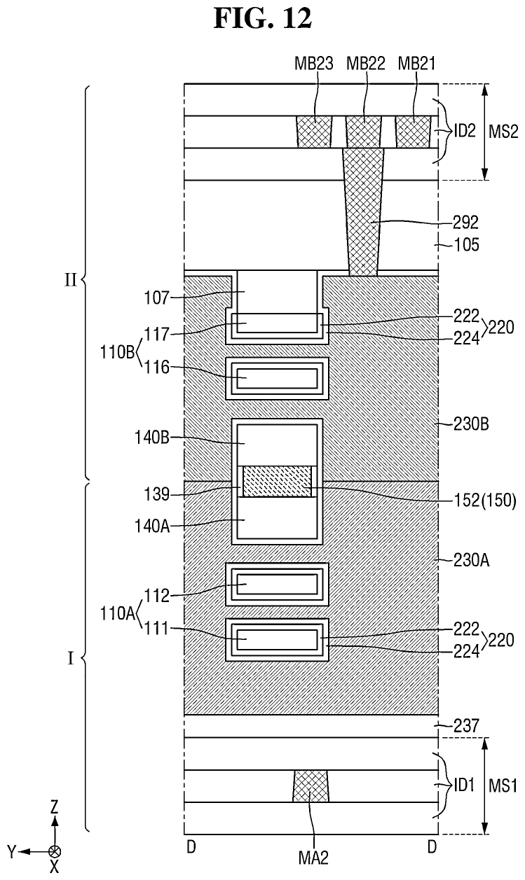

FIG. 9 is an example circuit diagram for explaining a semiconductor device according to some example embodiments. FIG. 10 is an example layout diagram for explaining the semiconductor device according to some example embodiments. FIG. 11 is a cross-sectional view taken along line C-C of FIG. 10. FIG. 12 is a cross-sectional view taken along line D-D of FIG. 10. For convenience of explanation, repeated parts of contents explained above using FIGS. 1 to 8 will be briefly explained or omitted.

Referring to FIG. 9, the semiconductor device according to some example embodiments may be provided as a NAND gate circuit.

For example, the semiconductor device according to some example embodiments may include a third transistor TR21, a fourth transistor TR22, a fifth transistor TR23, and a sixth transistor TR24 connected between the power supply node V_{DD} and the ground node V_{SS}. The third transistor TR21 and the fifth transistor TR23 may both be an NFET, and the fourth transistor TR22 and the sixth transistor TR24 may both be a PFET. The third transistor TR21 and the fourth transistor TR22 may be connected in series between the ground node V_{SS} and the output signal Vₒᵤₜ of the NAND gate. The fifth transistor TR23 and the sixth transistor TR24 may be connected in parallel between the power supply node V_{DD} and the output signal Vₒᵤₜ of the NAND gate.

A source of the third transistor TR21 may be connected to the ground node V_{SS}, and a source of the fifth transistor TR23 and a source of the sixth transistor TR24 may be connected to the power supply node V_{DD}. A first input signal Vᵢₙ₁ of the NAND gate may be input to the gate of the third transistor TR21 and the gate of the fifth transistor TR23, and a second input signal Vᵢₙ₂ of the NAND gate may be input to the gate of the fourth transistor TR22 and the gate of the sixth transistor TR24. The output signal Vₒᵤₜ of the NAND gate may be output from a node to which the source of the fourth transistor TR22, the drain of the fifth transistor TR23, and the drain of the sixth transistor TR24 are connected.

Referring to FIGS. 9 to 12, the semiconductor device according to some example embodiments may include a first active pattern 110A, a second active pattern 110B, second gate structures 230A and 230B, a second gate dielectric film 220, a second gate spacer 235, a second gate capping pattern 237, third gate structures 330A and 330B, a third gate dielectric film 320, a third gate spacer 335, a third gate capping pattern 337, a first source/drain region 160A, a second source/drain region 160B, an intermediate connecting layer 150, a first insulating pattern 140A, a second insulating pattern 140B, an intermediate spacer 139, an intermediate isolation layer 145, third source/drain contacts 271A to 273A, fourth source/drain contacts 271B to 273B, a first wiring structure MS1, and a second wiring structure MS2.

The second gate structures 230A and 230B and the third gate structures 330A and 330B may be arranged along the first direction X. The second gate structures 230A and 230B and the third gate structures 330A and 330B may each intersect the first active pattern 110A and the second active pattern 110B. For example, the second gate structures 230A and 230B and the third gate structures 330A and 330B may extend side by side in the second direction Y.

In some example embodiments, the second gate structures 230A and 230B may include a second lower gate electrode 230A intersecting the first active pattern 110A, and a second upper gate electrode 230B intersecting the second active pattern 110B. The first active pattern 110A may extend in the first direction X to penetrate the second lower gate electrode 230A, and the second active pattern 110B may extend in the first direction X to penetrate the second upper gate electrode 230B.

In some example embodiments, the third gate structures 330A and 330B may include a third lower gate electrode 330A intersecting the first active pattern 110A, and a third upper gate electrode 330B intersecting the second active pattern 110B. The first active pattern 110A may extend in the first direction X to penetrate the third lower gate electrode 330A, and the second active pattern 110B may extend in the first direction X to penetrate the third upper gate electrode 330B.

Because each of the second gate structures 230A and 230B and the third gate structures 330A and 330B may be similar to the first gate structures 130A and 130B explained above using FIGS. 2 to 5, the detailed explanation thereof will not be provided below.

The second gate dielectric film 220 may be interposed between the first active pattern 110A and the second lower gate electrode 230A, and between the second active pattern 110B and the second upper gate electrode 230B. In some example embodiments, the second gate dielectric film 220 may include a second interfacial film 222 and a second high dielectric film 224 that are sequentially stacked on the first active pattern 110A and the second active pattern 110B.

The third gate dielectric film 320 may be interposed between the first active pattern 110A and the third lower gate electrode 330A, and between the second active pattern 110B and the third upper gate electrode 330B. In some example embodiments, the third gate dielectric film 320 may include a third interfacial film 322 and a second high dielectric film 324 that are sequentially stacked on the first active pattern 110A and the second active pattern 110B.

Because each of the second gate dielectric film 220 and the third gate dielectric film 320 may each be similar to the first gate dielectric film 120 explained above using FIGS. 2 to 5, detailed explanation thereof will not be provided below.

The second gate spacer 235 may extend along the side faces of the second gate structures 230A and 230B. The second gate capping pattern 237 may extend along the lower surfaces of the second gate structures 230A and 230B. The third gate spacers 335 may extend along the side faces of the third gate structures 330A and 330B. The third gate capping pattern 337 may extend along lower surfaces of the third gate structures 330A and 330B.

Because each of the second gate spacer 235 and the third gate spacer 335 may be similar to the first gate spacer 135 explained above using FIGS. 2 to 5, and each of the second gate capping pattern 237 and the third gate capping pattern 337 may be similar to the first gate capping patterns 137 explained above using FIGS. 2 to 5, detailed descriptions thereof will not be provided below.

The third source/drain contacts 271A to 273A may be disposed inside the first region I. The third source/drain contacts 271A to 273A may each be connected to the first source/drain region 160A.

For example, a third lower source/drain contact 271A connected to the first source/drain region 160A on the side faces of the second gate structure 230A and 230B opposite to the third gate structure 330A and 330B may be formed, a fourth lower source/drain contact 272A connected to the first source/drain region 160A between the second gate structure 230A and 230B and the third gate structure 330A and 330B may be formed, and a fifth lower source/drain contact 273A connected to the first source/drain regions 160A on the side face of the third gate structures 330A and 330B opposite to the second gate structures 230A and 230B may be formed. In some example embodiments, each of the third source/drain contacts 271A to 273A may extend in the third direction Z and penetrate the interlayer insulating film 170.

In some example embodiments, the first source/drain region 160A connected to the third lower source/drain contact 271A may be electrically isolated from the intermediate connecting layer 150 by the intermediate isolation layer 145.

In some example embodiments, the first source/drain region 160A connected to the fourth lower source/drain contact 272A may be electrically isolated from the intermediate connecting layer 150 by the first intermediate insulating layer 145A.

In some example embodiments, a fifth lower source/drain contact 273A may connect the first source/drain region 160A and the intermediate contact layer 150. For example, the fifth lower source/drain contact 273A may penetrate the first source/drain region 160A, and be connected to the second intermediate conductive pattern 154.

The fourth source/drain contacts 271B to 273B may be disposed inside the second region II. The fourth source/drain contacts 271B to 273B may each be connected to the second source/drain region 160B.

For example, a third upper source/drain contact 271B connected to the second source/drain region 160B on the side faces of the second gate structure 230A and 230B opposite to the third gate structure 330A and 330B may be formed, a fourth upper source/drain contact 272B connected to the second source/drain region 160B between the second gate structures 230A and 230B and the third gate structure 330A and 330B may be formed, and a fifth upper source/drain contact 273B connected to the second source/drain region 160B on the side faces of the third gate structure 330A and 330B opposite to the second gate structures 230A and 230B may be formed. In some example embodiments, each of the fourth source/drain contacts 271B to 273B may extend in the third direction Z and penetrate the insulating substrate 105.

In some example embodiments, the second source/drain region 160B connected to the third upper source/drain contact 271B may be electrically isolated from the intermediate connecting layer 150 by the intermediate isolation layer 145.

In some example embodiments, the fourth upper source/drain contact 272B may connect the second source/drain region 160B and the intermediate contact layer 150. For example, the fourth upper source/drain contact 272B may penetrate the second source/drain region 160B, and be connected to the second intermediate conductive pattern 154.

In some example embodiments, the second source/drain region 160B connected to the fifth upper source/drain contact 273B may be electrically isolated from the intermediate connecting layer 150 by the second intermediate insulating layer 145B.

The fifth lower source/drain contact 273A and the fourth upper source/drain contact 272B may be electrically connected through the intermediate connecting layer 150. That is, the first source/drain region 160A connected to the fifth lower source/drain contact 273A and the second source/drain region 160B connected to the fourth upper source/drain contact 272B may be electrically connected.

The second input signal Vᵢₙ₂ of the NAND gate may be provided to the third gate structures 330A and 330B. For example, a second gate contact 291 connected to the third gate structures 330A and 330B may be formed. Also, the second wiring structure MS2 may include a fourth upper wiring pattern MB21 connected to the second gate contact 291. The fourth upper wiring pattern MB21 may provide the second input signal Vᵢₙ₂. The second input signal Vᵢₙ₂ of the fourth upper wiring pattern MB21 may be input to the gates of the fourth transistor TR22 and the sixth transistor TR24 (that is, the third gate structures 330A and 330B) through the second gate contact 291. In some various embodiments, the fourth upper wiring pattern MB21 may extend long in the first direction X.

The first input signal Vᵢₙ₁ of the NAND gate may be provided to the second gate structures 230A and 230B (refer to FIG. 9). For example, a third gate contact 292 connected to the second gate structures 230A and 230B may be formed. Also, the second wiring structure MS2 may include a fifth upper wiring pattern MB22 connected to the third gate contact 292. The fifth upper wiring pattern MB22 may provide the first input signal Vᵢₙ₁. The first input signal Vᵢₙ₁ of the fifth upper wiring pattern MB22 may be input to the gates of the third transistor TR21 and the fifth transistor TR23 (that is, the second gate structures 230A and 230B) through the third gate contact 292. In some example embodiments, the fifth upper wiring pattern MB22 may extend long in the first direction X.

Although only an example in which the wiring patterns that provide the input signals Vᵢₙ₁ and Vᵢₙ₂ of the NAND gate are included in the second wiring structure MS2, this is merely an example. At least part of the wiring patterns that provide the input signals Vᵢₙ₁ and Vᵢₙ₂ of the NAND gates may be included in the first wiring structure MS1.

A third lower source/drain contact 271A may be connected to the ground node V_{SS}. For example, a third lower contact via 281A connected to the third lower source/drain contact 271A may be formed. Also, the first wiring structure MS1 may include a second lower wiring pattern MA2 connected to the third lower contact via 281A. The second lower wiring pattern MA2 may be provided as the ground node V_{SS}. The ground node V_{SS} of the second lower wiring pattern MA2 may be connected to the source of the third transistor TR21 (that is, the first source/drain region 160A connected to the third lower source/drain contact 271A) through the third lower contact via 281A. In some example embodiments, the second lower wiring pattern MA2 may extend long in the first direction X.

The third upper source/drain contact 271B and the fifth upper source/drain contact 273B may be connected to the power supply node V_{DD}. For example, the third upper contact via 281B connected to the third upper source/drain contact 271B and the fifth upper contact via 283B connected to the fifth upper source/drain contact 273B may be formed. Also, the second wiring structure MS2 may include a sixth upper wiring pattern MA23 connected to the third upper contact via 281B and the fifth upper contact via 283B. The sixth upper wiring pattern MA23 may be provided as the power supply node V_{DD}. The power supply node V_{DD} of the sixth upper wiring pattern MA23 may be connected to the source of the fifth transistor TR23 (that is, the second source/drain region 160B connected to the third upper source/drain contact 271B) through the third upper contact via 281B, and may be connected to the source of the sixth transistor TR24 (that is, the second source/drain region 160B connected to the fifth upper source/drain contact 273B) through the fifth upper contact via 283B. In various example embodiments, the sixth upper wiring pattern MA23 may extend long in the first direction X.

The second wiring structure MS2 may include a seventh upper wiring pattern MA24 provided as the output signal Vₒᵤₜ of the NAND gate. For example, a fourth upper contact via 282B connected to the fourth upper source/drain contact 272B may be formed. The seventh upper wiring pattern MA24 may be connected to the drains of the fifth transistor TR23 and the sixth transistor TR24 (i.e., the second source/drain regions 160B connected to the fourth upper source/drain contact 272B), and the source of the fourth transistor TR22 (i.e., the first source/drain region 160A connected to the fifth lower source/drain contact 273A), through the fourth upper contact via 282B and the intermediate connecting layer 150.

Although the wiring pattern provided as the output signal Vₒᵤₜ of the NAND gate is described only as being included inside the second wiring structure MS2, this is merely an example. The wiring pattern provided as the output signal Vₒᵤₜ of the NAND gate may be included in the first wiring structure MS1.

As semiconductor devices become more and more highly integrated, individual circuit patterns are further miniaturized to realize more semiconductor devices in the same area. For this purpose, a semiconductor device using a stacked multi-gate transistor in which a multi-gate transistor of an upper region (e.g., a second region II) is stacked on a multi-gate transistor of a lower region (e.g., a first region I) is being researched. However, such a semiconductor device may have a problem in that it may be difficult to improve the degree of integration due to the complexity of the circuit pattern.

For example, a long via extending across the lower and upper regions may be provided to connect the transistor of the lower region and the transistor of the upper region. However, because the area adjacent to the gate structure is larger than the via extending only in the lower region or the via extending only in the upper region, such a long via may cause a degradation of performance of the semiconductor device, by increasing the parasitic capacitance with the gate structure and/or slowing the performance thereof. Alternatively or additionally, because such a long via may be disposed outside the region in which the active pattern and the gate structure are disposed from a planar viewpoint (e.g., because the via does not overlap the active pattern and the gate structure in the vertical direction (e.g., the third direction Z)), the long via becomes a cause of limiting the degree of integration, by increasing the area required to realize the semiconductor device.

In contrast, the semiconductor device according to various example embodiments may connect the transistor of the first region I and the transistor of the second region II, by using the intermediate connecting layer 150. Specifically, as explained above, the intermediate connecting layer 150 may be interposed between the first active pattern 110A and the second active pattern 110B, and between the first source/drain region 160A and the second source/drain region 160B. The intermediate connecting layer 150 may be used to connect at least a part of the source/drain contacts (e.g., 171A and 172A, and 271A to 273A) of the first region I and at least a part of the source/drain contacts (e.g., 171B and 172B, and 271B to 273B) of the second region II. Because such an intermediate connecting layer 150 not only has a significantly smaller area adjacent to the gate structure, but also may overlap the first active pattern 110A and the second active pattern 110B from a planar viewpoint, a semiconductor device including the intermediate connecting layer 150 does or may not require an additional area to realize a semiconductor device. This may make it possible to provide a semiconductor device having improved integration and performance.

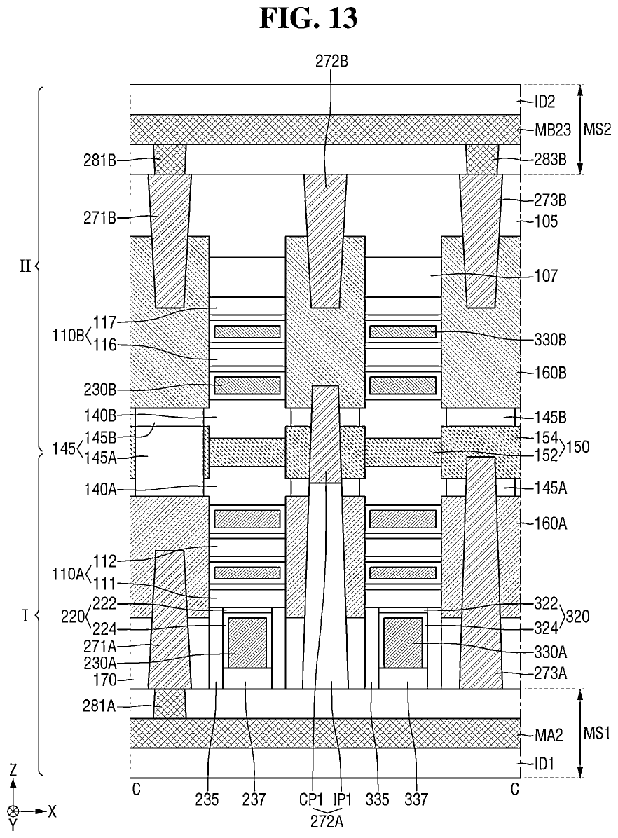

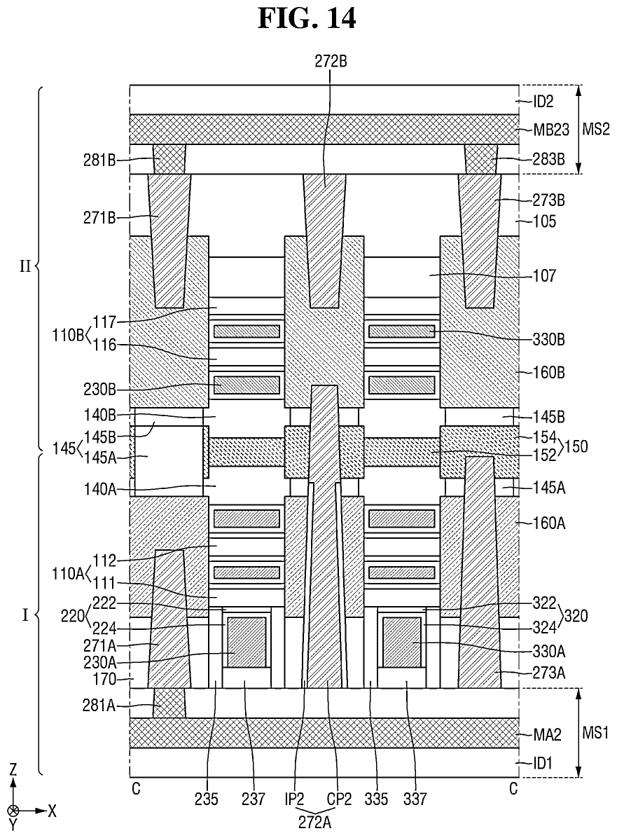

FIGS. 13 and 14 are various cross-sectional views for explaining a semiconductor device according to some example embodiments. For convenience of explanation, repeated parts of contents explained above using FIGS. 1 to 12 will be briefly explained or omitted.

Referring to FIGS. 9, 10, 13 and 14, in the semiconductor device according to some example embodiments, the fourth lower source/drain contact 272A may connect the second source/drain region 160B and the intermediate contact layer 150.

For example, the fourth lower source/drain contact 272A may penetrate the first source/drain region 160A and the second intermediate conductive pattern 154, and be connected to the second source/drain region 160B. The fourth lower source/drain contact 272A may be electrically isolated from the first source/drain region 160A.

As an example, as shown in FIG. 13, the fourth lower source/drain contact 272A may include a first contact part CP1 and a first insulating part IP1. The first contact part CP1 may penetrate the second intermediate conductive pattern 154, and be connected to the second source/drain region 160B. The first contact part CP1 may include a conductive material to electrically connect the second intermediate conductive pattern 154 and the second source/drain regions 160B. The first insulating part IP1 may be formed on the lower surface of the first contact part IP1. The first insulating part IP1 may fill a region between the first contact part CP1 and the first wiring structure MS1. In some example embodiments, the upper surface of the first insulating part IP1 may be formed to be higher than the upper surface of the first source/drain region 160A. The first insulating part IP1 may include an insulating material, and may electrically isolate the first contact part CP1 and the first source/drain region 160A.

alternatively or additionally, as shown in FIG. 14, the fourth lower source/drain contact 272A may include a second contact part CP2 and a second insulating part IP2. The second contact part CP2 penetrates the first source/drain region 160A and the second intermediate conductive pattern 154, and may be connected to the second source/drain region 160B. The second contact part CP2 may include a conductive material to electrically connect the second intermediate conductive pattern 154 and the second source/drain regions 160B. The second insulating part IP2 may extend along a part of the side face of the second contact part IP2. The second insulating part IP2 may be interposed between the second contact part CP2 and the first source/drain region 160A. Also, the upper surface of the second insulating part IP2 may be formed to be lower than the upper surface of the second intermediate conductive pattern 154. The second insulating part IP2 may include an insulating material to electrically isolate the second contact part CP2 and the second source/drain region 160A.

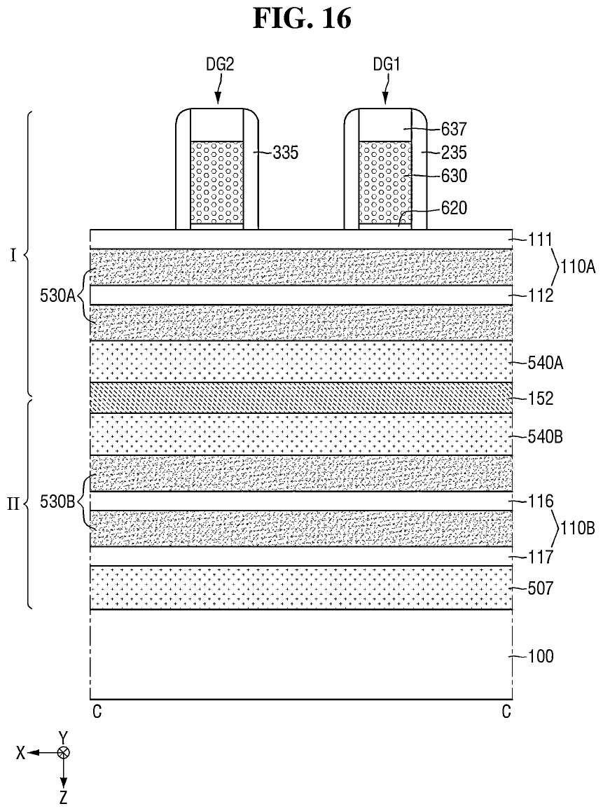

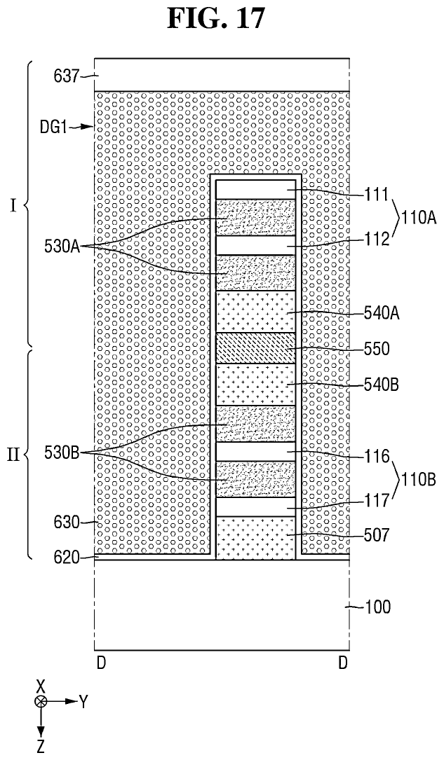

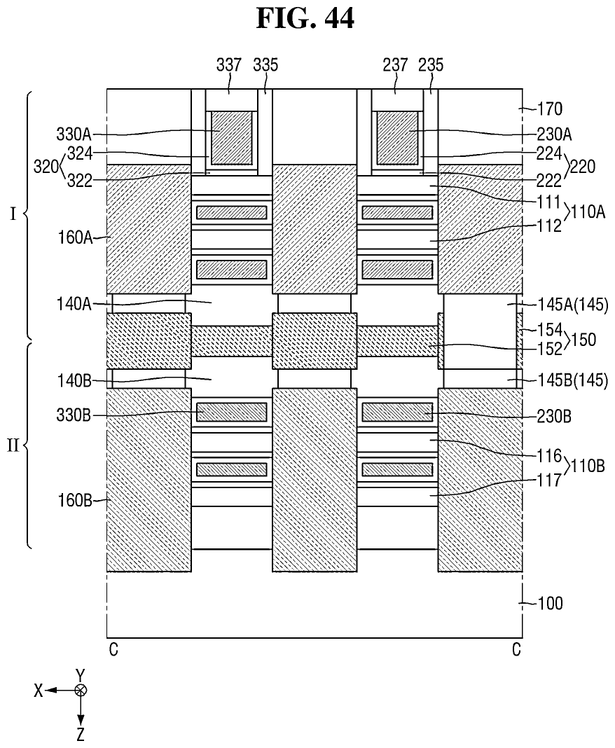

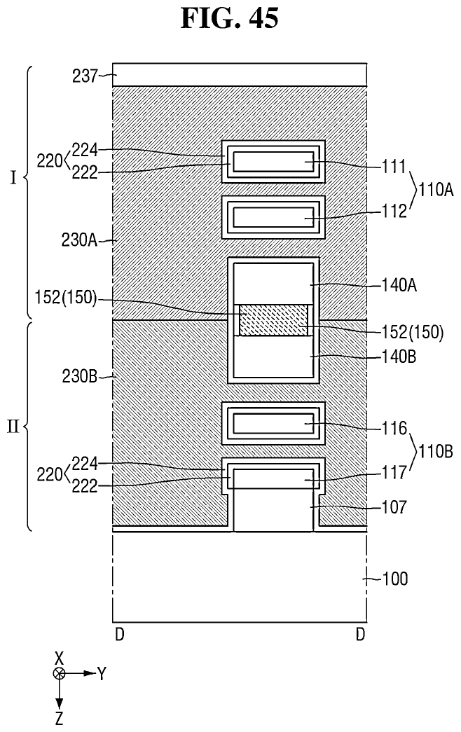

A method for fabricating a semiconductor device according to various example embodiments will be described below with reference to FIGS. 10 to 52.

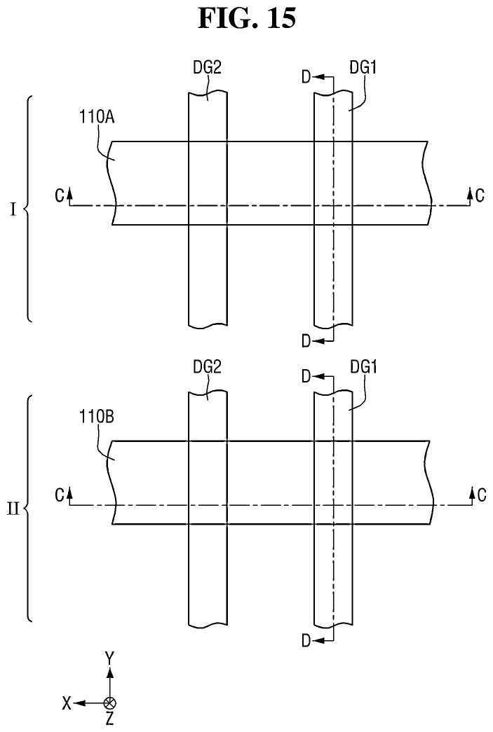

FIGS. 15 to 52 are intermediate step diagrams for explaining the method for fabricating the semiconductor device according to some example embodiments. For convenience of explanation, repeated parts of contents explained above using FIGS. 1 to 12 will be briefly explained or omitted.

Referring to FIGS. 15 to 17, a base sacrificial pattern 507, a second active pattern 110B, a second sacrificial pattern 530B, a second intermediate sacrificial pattern 540B, a first intermediate conductive pattern 152, a first intermediate sacrificial pattern 540A, a first sacrificial pattern 530A, a first active pattern 110A, a first dummy gate structure DG1, a second dummy gate structure DG2, a second gate spacer 235, and a third gate spacer 335 are formed on the base substrate 100, e.g., with a process such as but not limited to one or more of a chemical vapor deposition process such as a plasma-enhanced CVD process and/or a low pressure CVD process and/or an atomic layer deposition process.

The base sacrificial pattern 507 may be stacked on the base substrate 100. The second active pattern 110B and the second sacrificial pattern 530B may be stacked on the base sacrificial pattern 507. The second intermediate sacrificial pattern 540B may be stacked on the second active pattern 110B and the second sacrificial pattern 530B. The second active pattern 110B and the second sacrificial pattern 530B may be alternately stacked. For example, the second sacrificial pattern 530B may be interposed between a first upper bridge pattern 116 and a second upper bridge pattern 117, and between the first upper bridge pattern 116 and the second intermediate sacrificial pattern 540B.

The first intermediate conductive pattern 152 may be stacked on the second intermediate sacrificial pattern 540B. The first intermediate sacrificial pattern 540A may be stacked on the first intermediate conductive pattern 152. The first active pattern 110A and the first sacrificial pattern 530A may be stacked on the first intermediate sacrificial pattern 540A. For example, the first sacrificial pattern 530A may be interposed between the first intermediate sacrificial pattern 540A and the second lower bridge pattern 112, and between the first lower bridge pattern 111 and the second lower bridge pattern 112.

The base sacrificial pattern 507, the first intermediate sacrificial pattern 540A and the second intermediate sacrificial pattern 540B may have an etching selectivity with respect to the first active pattern 110A, the first sacrificial pattern 530A, the second active pattern 110B and the second sacrificial pattern 530B. Also, the first sacrificial pattern 530A and the second sacrificial pattern 530B may have an etching selectivity, e.g., an etch rate difference, with respect to the first active pattern 110A and the second active pattern 110B. As an example, the first active pattern 110A and the second active pattern 110B may each include a silicon (Si) film. As an example, the first sacrificial pattern 530A and the second sacrificial pattern 530B may each include a silicon germanium (SiGe) film having a first concentration of germanium (Ge). As an example, the base sacrificial pattern 507, the first intermediate sacrificial pattern 540A, and the second intermediate sacrificial pattern 540B may each include a silicon germanium (SiGe) film having a second concentration of germanium (Ge) greater than the first concentration.

Next, the first dummy gate structure DG1 and the second dummy gate structure DG2 are formed. The first dummy gate structure DG1 and the second dummy gate structure DG2 may extend side by side in the second direction Y.

In some example embodiments, each of the dummy gate structures DG1 and DG2 may include a dummy gate dielectric film 620 and a dummy gate electrode 630 that are stacked sequentially. For example, a dielectric film and an electrode film stacked on the first active pattern 110A sequentially may be formed. Subsequently, a mask pattern 637 extending side by side in the second direction Y may be formed on the electrode film. A patterning process for patterning the dielectric film and the electrode film using the mask pattern 637 as an etching mask may then be performed.

Each of the dummy gate structures DG1 and DG2 may have an etching selectivity, e.g., an etch rate difference, with respect to the first active pattern 110A and the second active pattern 110B. As an example, the dummy gate electrode 630 may include polysilicon (poly Si).

Next, the second gate spacer 235 extending along the side face of the first dummy gate structure DG1 and the third gate spacer 335 extending along the side face of the second dummy gate structure DG2 may be formed.

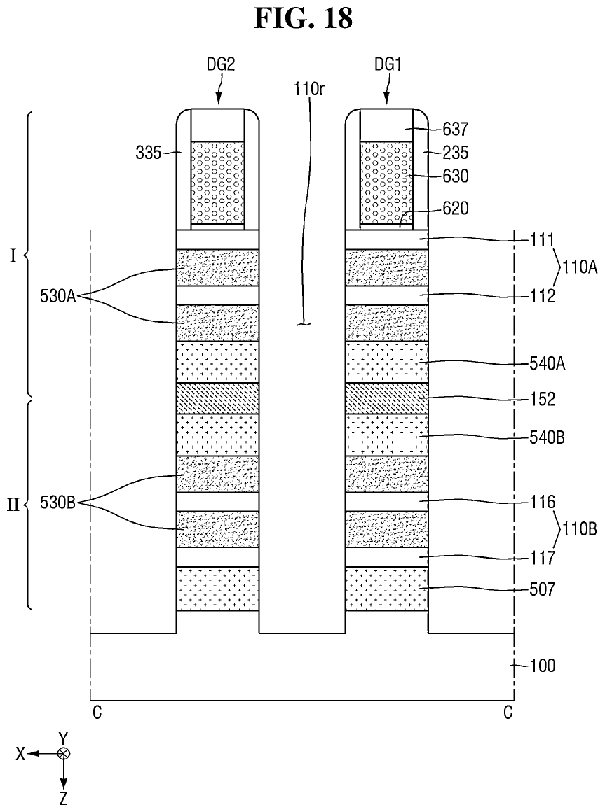

Referring to FIG. 18, a source/drain recess 110r is formed inside the base sacrificial pattern 507, the second active pattern 110B, the second sacrificial pattern 530B, the second intermediate sacrificial pattern 540B, the first intermediate conductive pattern 152, the first intermediate sacrificial pattern 540A, the first sacrificial pattern 530A, and the first active pattern 110A.

For example, an etching process in which the first dummy gate structure DG1, the second gate spacer 235, the second dummy gate structure DG2, and the second gate spacer 235 are used as an etching mask may be performed.

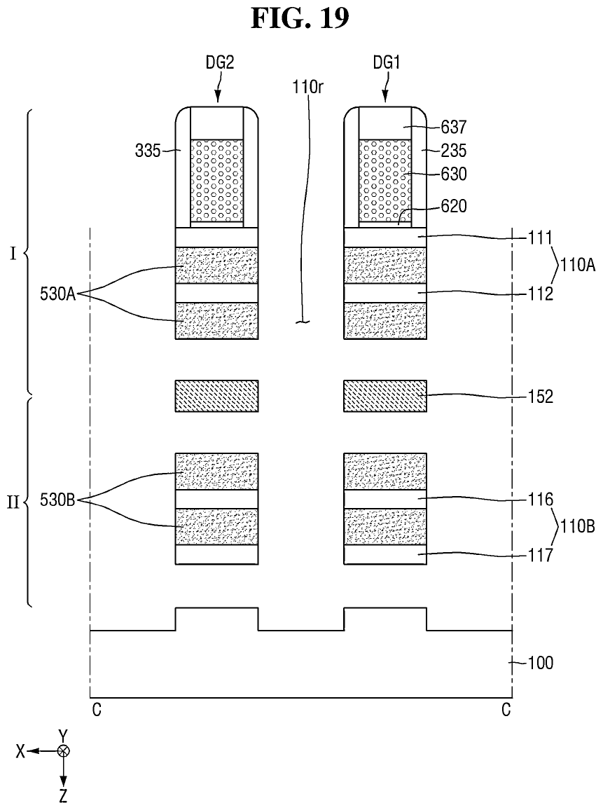

Referring to FIG. 19, the base sacrificial pattern 507, the first intermediate sacrificial pattern 540A, and the second intermediate sacrificial pattern 540B are removed.

For example, a selective etching process may be performed on the base sacrificial pattern 507, the first intermediate sacrificial pattern 540A, and the second intermediate sacrificial pattern 540B exposed from the source/drain recesses 110r. Since the base sacrificial pattern 507, the first intermediate sacrificial pattern 540A and the second intermediate sacrificial pattern 540B may have an etching selectivity with respect to the first active pattern 110A, the first sacrificial pattern 530A, the second active pattern 110B and the second sacrificial pattern 530B, they may be selectively removed.

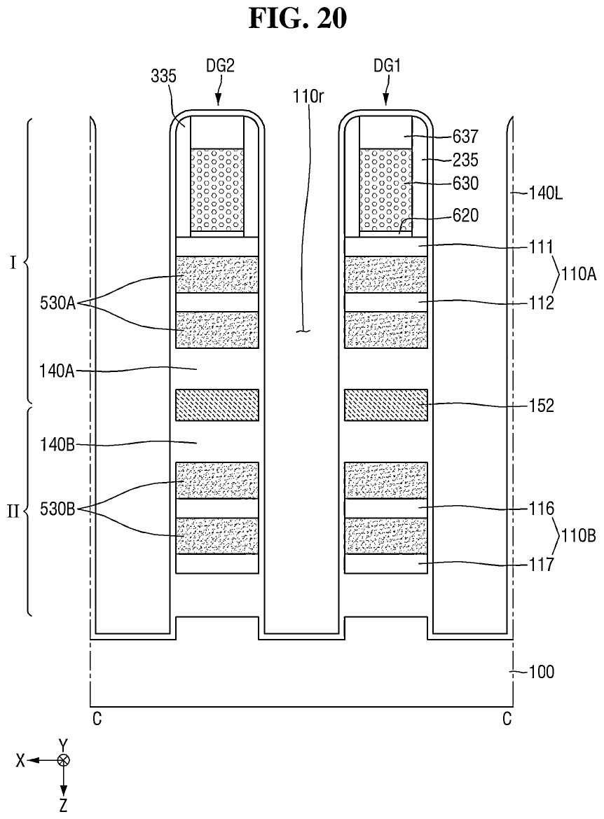

Referring to FIG. 20, a first spacer film 140L is formed.

The first spacer film 140L may cover the resulting product of FIG. 19. The first spacer film 140L may include, but not limited to, an insulating material, for example, at least one of silicon oxide, silicon oxynitride, silicon oxycarbonitride, and combinations thereof. For example, the first spacer film 140L may include a silicon nitride film.

The first spacer film 140L may fill the region in which the base sacrificial pattern 507, the first intermediate sacrificial pattern 540A, and the second intermediate sacrificial pattern 540B are removed. Accordingly, the base insulating pattern 107 may be formed between the base substrate 100 and the second active pattern 110B, the second insulating pattern 140B may be formed between the second active pattern 110B and the first intermediate conductive pattern 152, and the first insulating pattern 140A may be formed between the first active pattern 110A and the first intermediate conductive pattern 152.

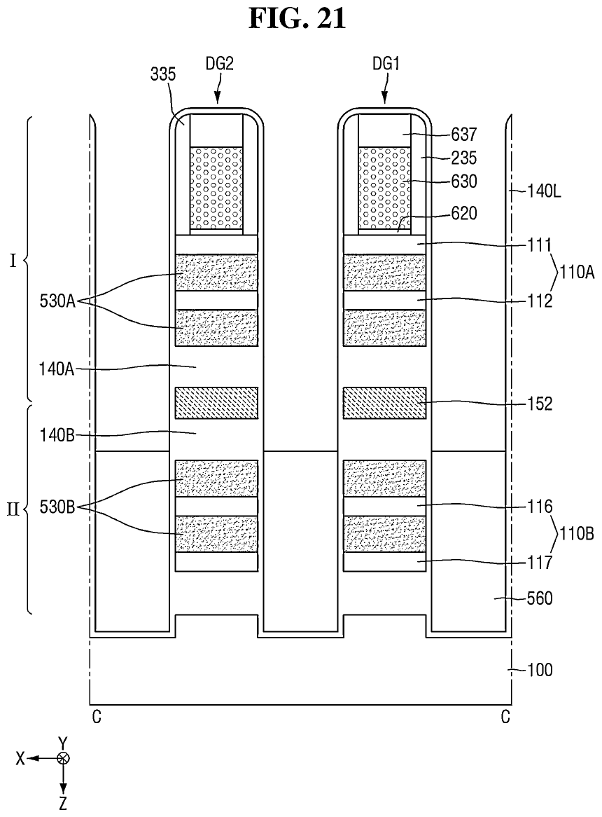

Referring to FIG. 21, the source/drain sacrificial film 560 is formed on the first spacer film 140L.

The source/drain sacrificial film 560 may fill a part of the source/drain recess 110r disposed in the second region II. For example, a sacrificial film which fills the source/drain recesses 110r may be formed, and a recess process may be performed on the sacrificial film. The upper surface of the source/drain sacrificial film 560 may be formed to be higher than the upper surface of the second active pattern 110B and lower than the lower surface of the first intermediate conductive pattern 152. The source/drain sacrificial film 560 may include, for example, but not limited to, a silicon oxide film.

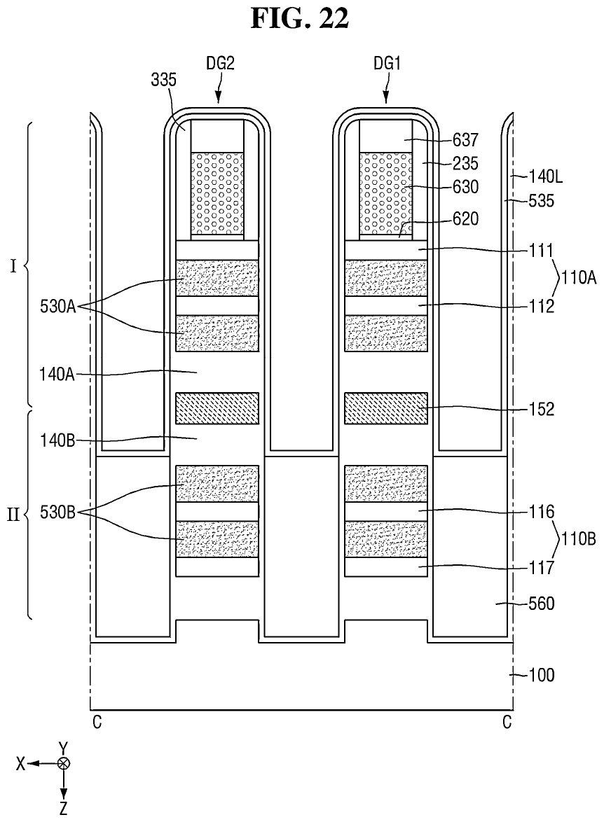

Referring to FIG. 22, a second spacer film 535 is formed on the first spacer film 140L and the source/drain sacrificial film 560.

The second spacer film 535 may cover the resulting product of FIG. 21. The second spacer film 535 may include an insulating material, for example, but not limited to, at least one of silicon oxide, silicon oxynitride, silicon oxycarbonitride, and combinations thereof. As an example, the second spacer film 535 may include a silicon nitride film.

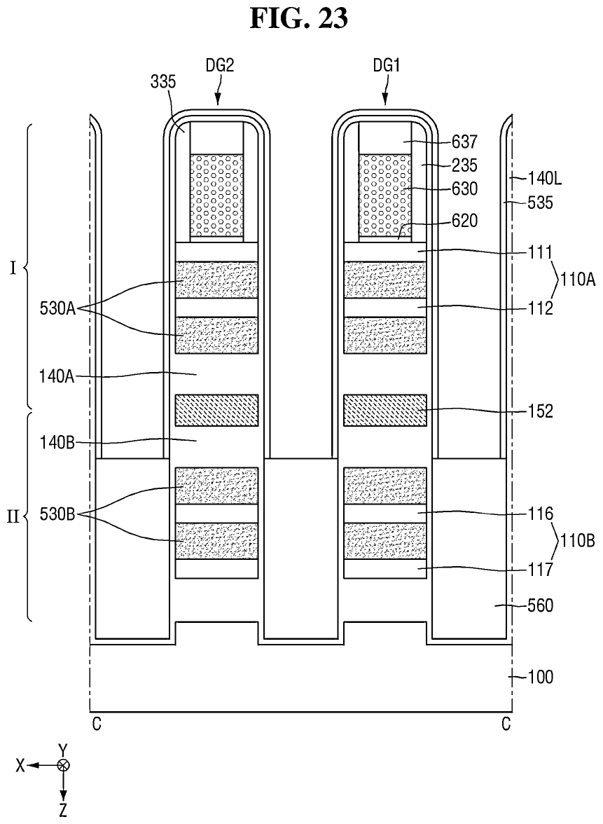

Referring to FIG. 23, the upper surface of the source/drain sacrificial film 560 is exposed.

For example, a lower part of the second spacer film 535 extending along the upper surface of the source/drain sacrificial film 560 may be removed.

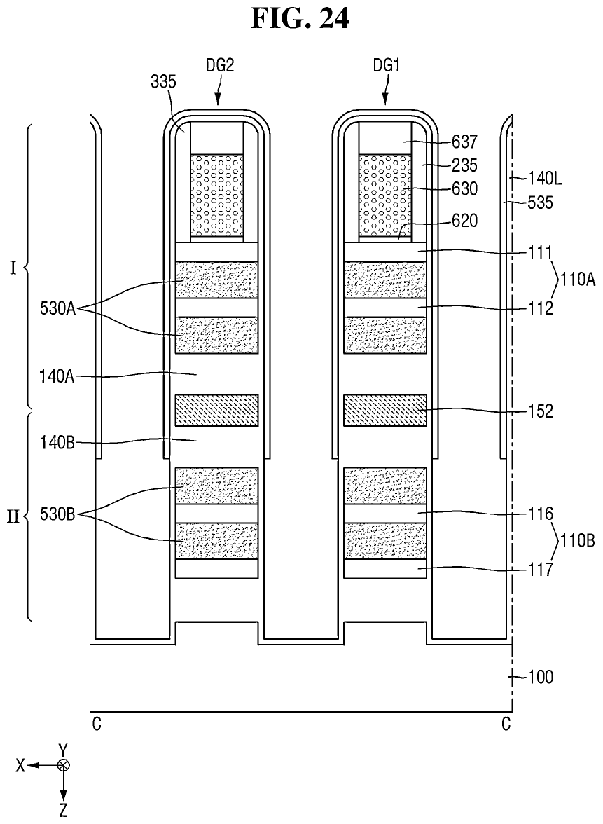

Referring to FIG. 24, the source/drain sacrificial film 560 is removed.

The source/drain sacrificial film 560 may be selectively removed with respect to the first spacer film 140L and the second spacer film 535. As the source/drain sacrificial film 560 is removed, a part of the first spacer film 140L disposed inside the second region II may be exposed from the second spacer film 535.

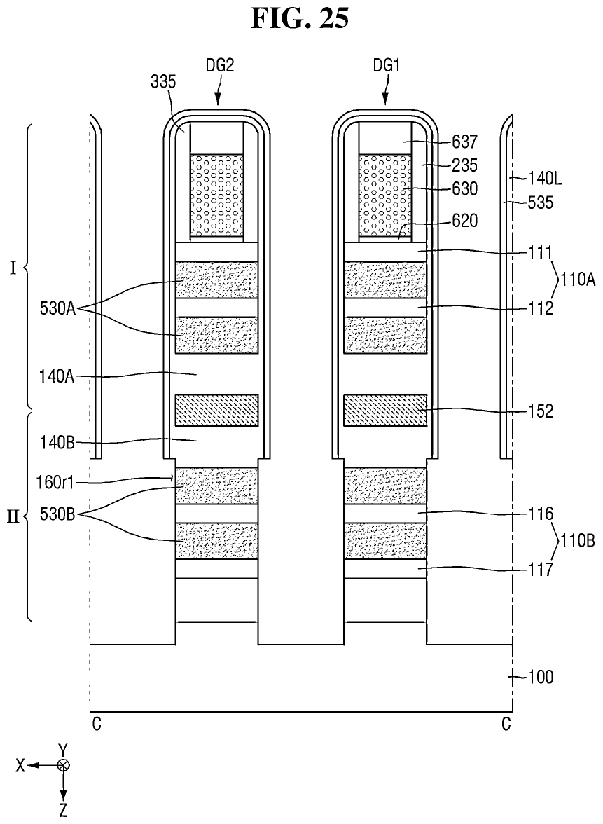

Referring to FIG. 25, the etching process is performed on the first spacer film 140L exposed from the second spacer film 535.

As the etching process is performed, the first spacer film 140L exposed from the second spacer film 535 may be removed to form a lower recess 160r1. The lower recess 160r1 may expose the upper surface of the base substrate 100, the side face of the base insulating pattern 107, the side face of the second active pattern 110B, and the side face of the second sacrificial pattern 530B.

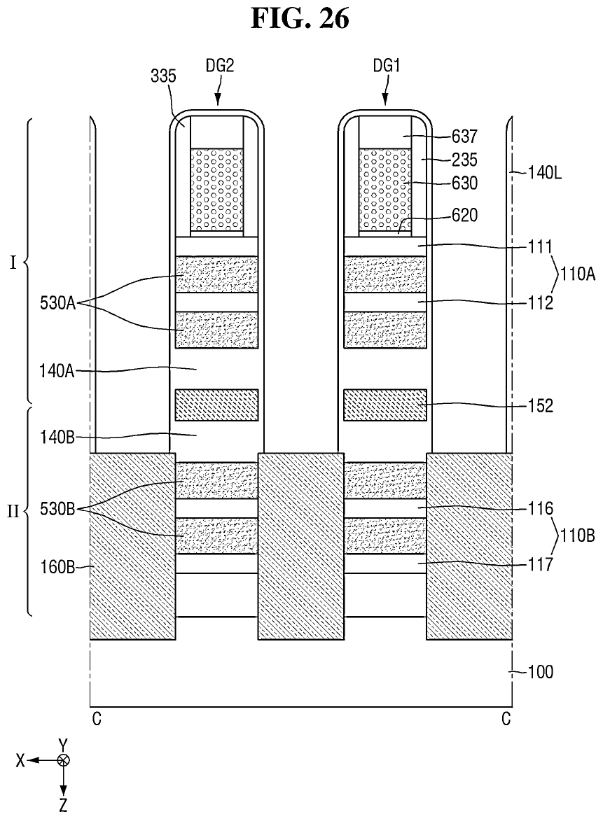

Referring to FIG. 26, the second source/drain region 160B is formed.

For example, an epitaxial growth process in which the base substrate 100, the second active pattern 110B and the second sacrificial pattern 530B exposed by the lower recess 160r1 are used as seed layers may be performed. Accordingly, the second source/drain region 160B connected to the second active pattern 110B may be formed.

The second spacer film 535 may be removed. The second spacer film 535 may be removed before the second source/drain region 160B is formed, or may be removed after the second source/drain region 160B is formed.

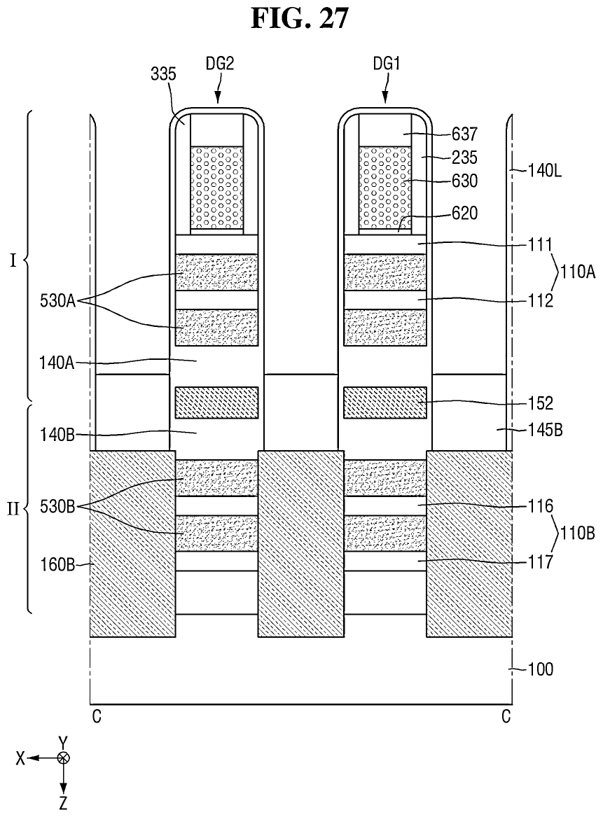

Referring to FIG. 27, a second intermediate insulating layer 145B is formed on the first spacer film 140L and the second source/drain region 160B.

The second intermediate insulating layer 145B may fill a part of the source/drain recess 110r adjacent to the first intermediate conductive pattern 152. For example, an insulating film which fills the source/drain recess 110r may be formed, and a recess process may be performed on the insulating film. The upper surface of the second intermediate insulating layer 145B may be formed to be higher than the upper surface of the first intermediate conductive pattern 152 and lower than the lower surface of the first active pattern 110A.

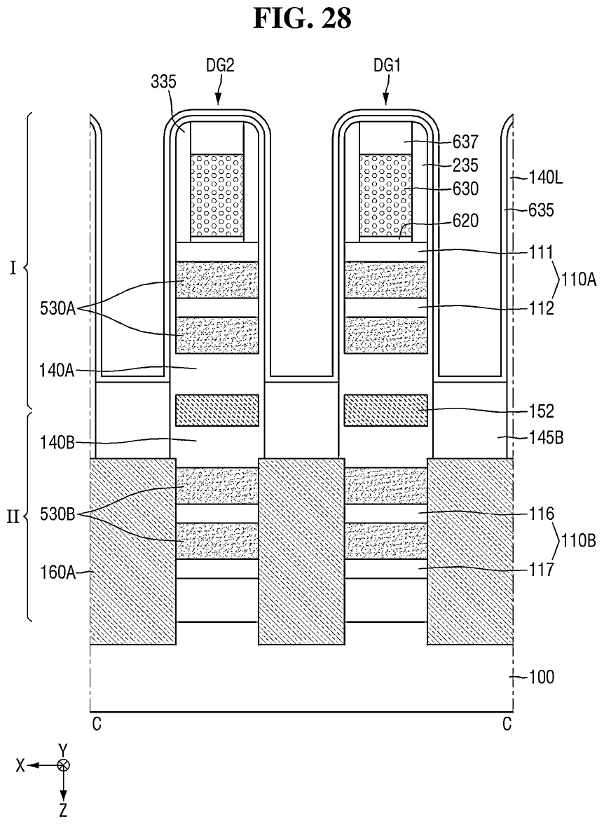

Referring to FIG. 28, a third spacer film 635 is formed on the first spacer film 140L and the second intermediate insulating layer 145B.

The third spacer film 635 may cover the resulting product of FIG. 27. The third spacer film 635 may include an insulating material, for example, but not limited to, at least one of silicon oxide, silicon oxynitride, silicon oxycarbonitride, and combinations thereof. For example, the third spacer film 635 may include a silicon nitride film.

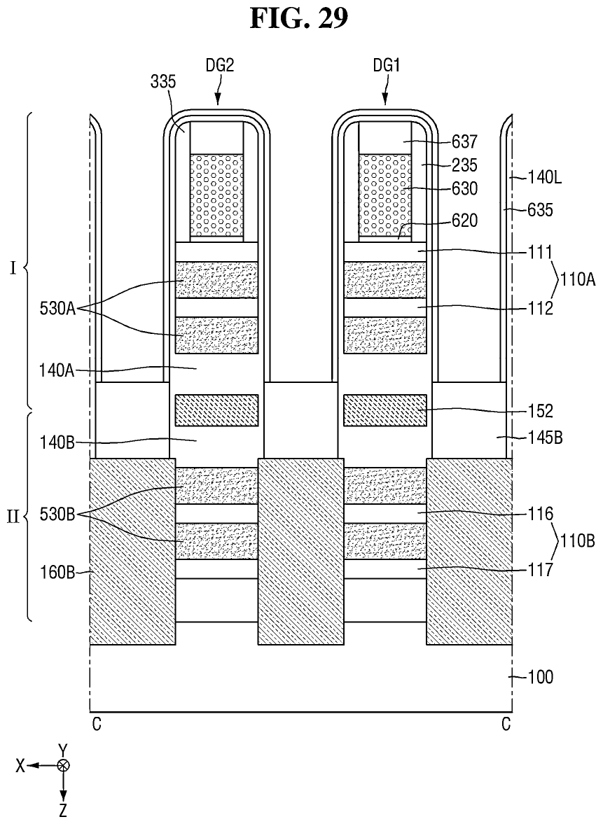

Referring to FIG. 29, the upper surface of the second intermediate insulating layer 145B is exposed.

For example, a lower part of the third spacer film 635 extending along the upper surface of the second intermediate insulating layer 145B may be removed.

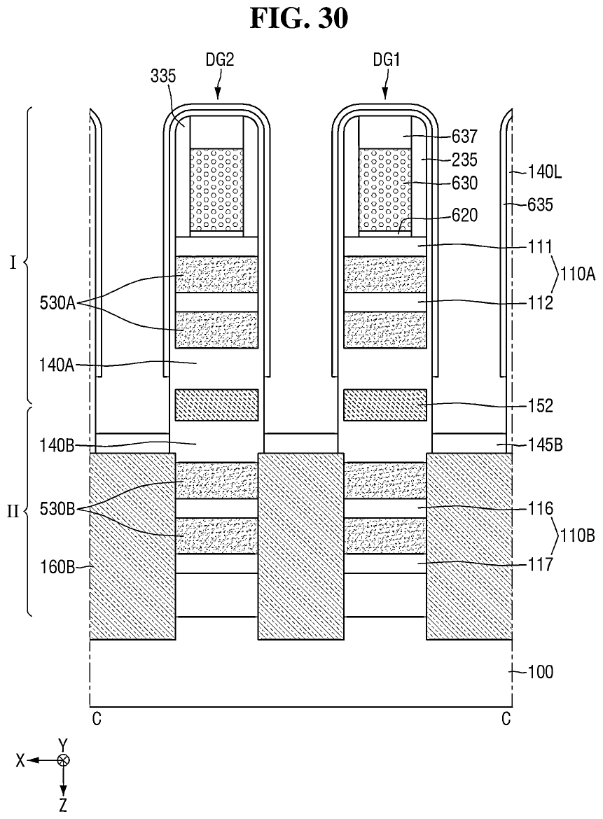

Referring to FIG. 30, a recess process is performed on the second intermediate insulating layer 145B.

The upper surface of the second intermediate insulating layer 145B may be formed to be lower than the upper surface of the first intermediate conductive pattern 152. In some example embodiments, the upper surface of the second intermediate insulating layer 145B may be formed to be lower than the lower surface of the first intermediate conductive pattern 152.

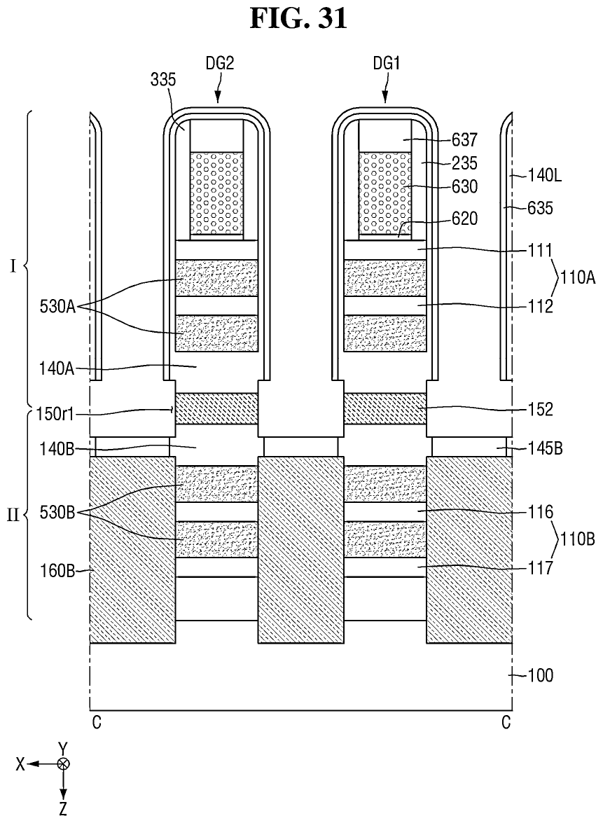

Referring to FIG. 31, an etching process is performed on the first spacer film 140L exposed from the third spacer film 635 and the second intermediate insulating layer 145B.

As the etching process is performed, the first spacer film 140L exposed from the third spacer film 635 and the second intermediate insulating layer 145B may be removed to form a first central recess 150r1. The first central recess 150r1 may expose the side face of the first intermediate conductive pattern 152.

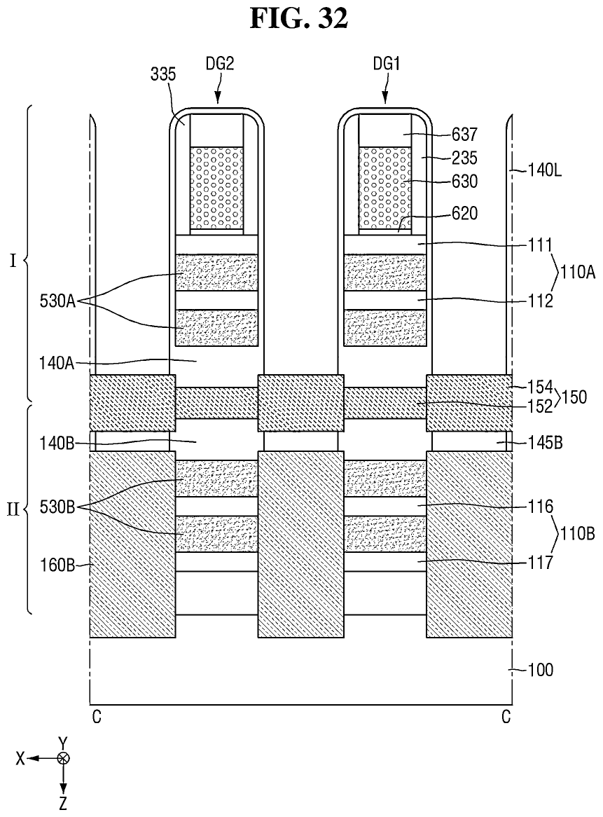

Referring to FIG. 32, the second intermediate conductive pattern 154 is formed.

For example, an epitaxial growth process in which the first intermediate conductive pattern 152 exposed by the first central recess 150r1 is used as a seed layer may be performed. Accordingly, the second intermediate conductive pattern 154 connected to the first intermediate conductive pattern 152 may be formed. The first intermediate conductive pattern 152 and the second intermediate conductive pattern 154 may be alternately connected in the first direction X to form the intermediate connecting layer 150 extending in the first direction X.

The third spacer film 635 may be removed. The third spacer film 635 may be removed before the second intermediate conductive pattern 154 is formed, or may be removed after the second intermediate conductive pattern 154 is formed.

In some example embodiments, a doping process may be performed on the second intermediate conductive pattern 154 after the second intermediate conductive pattern 154 is formed.

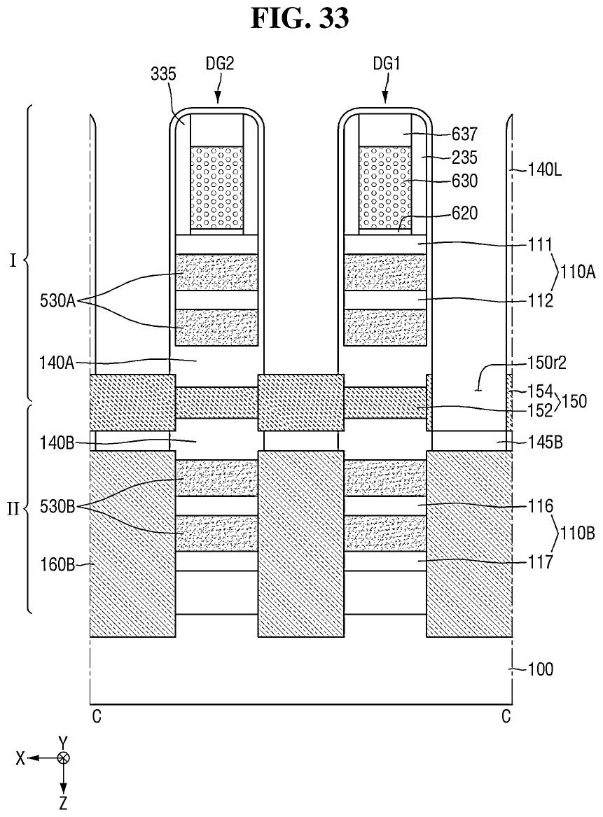

Referring to FIG. 33, a part of the intermediate connecting layer 150 is cut.

For example, an etching process for removing a part of the second intermediate conductive pattern 154 exposed from the source/drain recess 110r may be performed. As the etching process is performed, the second intermediate conductive pattern 154 may be cut to form a second central recess 150r2 that exposes a part of the second intermediate insulating layer 145B.

In some example embodiments, all of the second intermediate conductive pattern 154 may be cut. Alternatively or additionally in some example embodiments, all of the second intermediate conductive pattern 154 may not be cut.

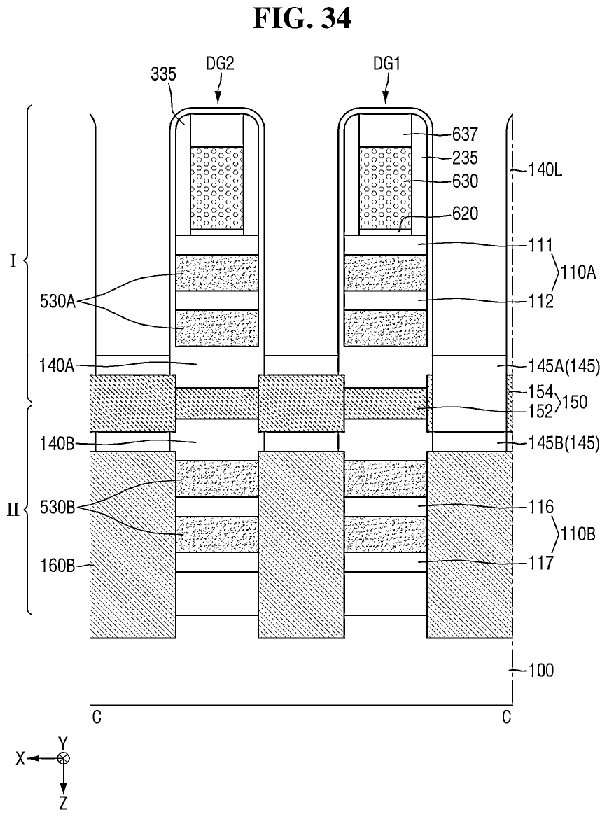

Referring to FIG. 34, the first intermediate insulating layer 145A is formed on the second intermediate conductive pattern 154 and the second intermediate insulating layer 145B.

The first intermediate insulating layer 145A may cover the upper surface of the second intermediate conductive pattern 154. In addition, the first intermediate insulating layer 145A may fill the region in which the second intermediate conductive pattern 154 is cut. For example, an insulating film which fills the source/drain recess 110r may be formed, and a recess process may be performed on the insulating film. The upper surface of the first intermediate insulating layer 145A may be formed to be higher than the upper surface of the second intermediate conductive pattern 154 and lower than the lower surface of the first active pattern 110A. Accordingly, the intermediate isolation layer 145 including the first intermediate insulating layer 145A and the second intermediate insulating layer 145B may be formed.

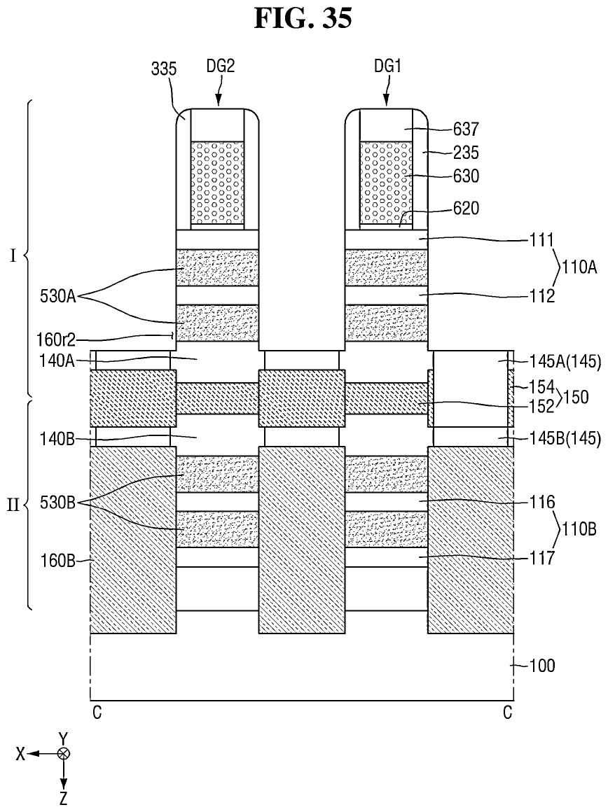

Referring to FIG. 35, the etching process is performed on the first spacer film 140L exposed from the intermediate isolation layer 145.

As the etching process is performed, the first spacer film 140L exposed from the intermediate isolation layer 145 may be removed to form an upper recess 160r2. The upper recess 160r2 may expose the side face of the first active pattern 110A and the side face of the first sacrificial pattern 530A.

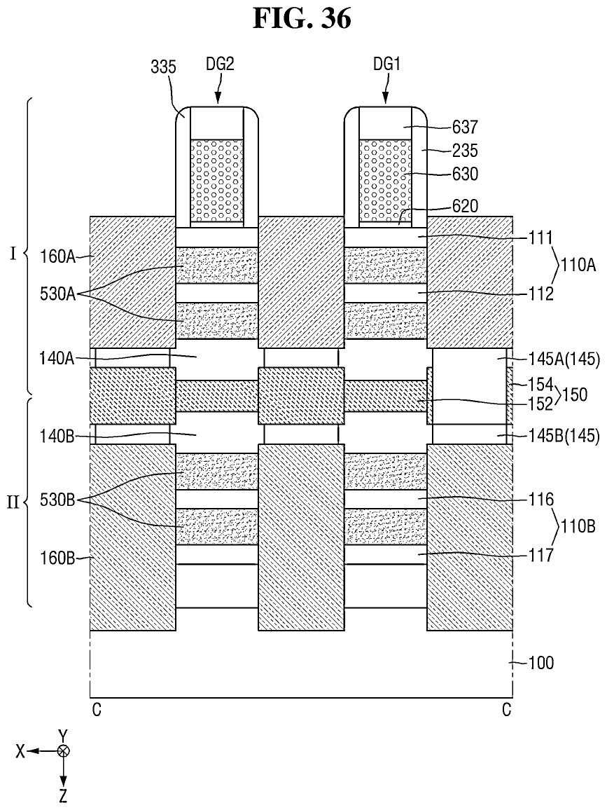

Referring to FIG. 36, the first source/drain region 160A is formed.

For example, an epitaxial growth process in which the first active pattern 110A and the first sacrificial pattern 530A exposed by the upper recess 160r2 are used as seed layers may be performed. Accordingly, the first source/drain region 160A connected to the first active pattern 110A may be formed.

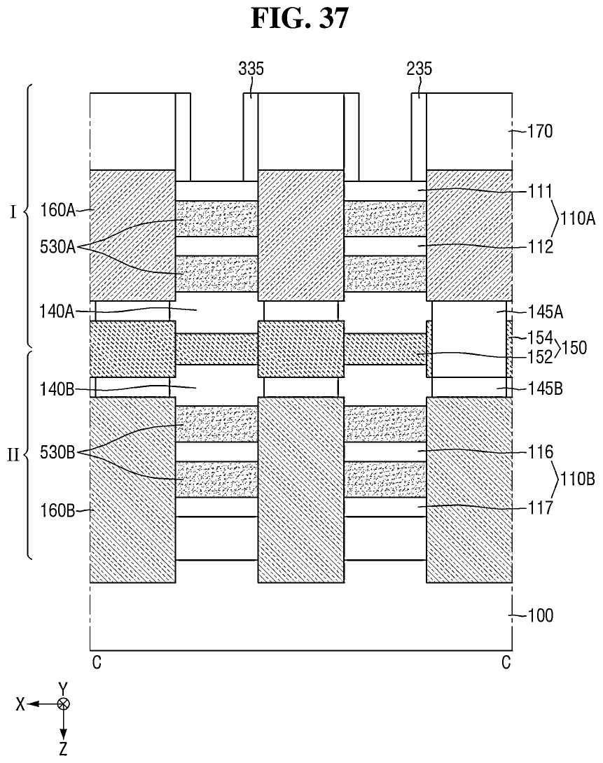

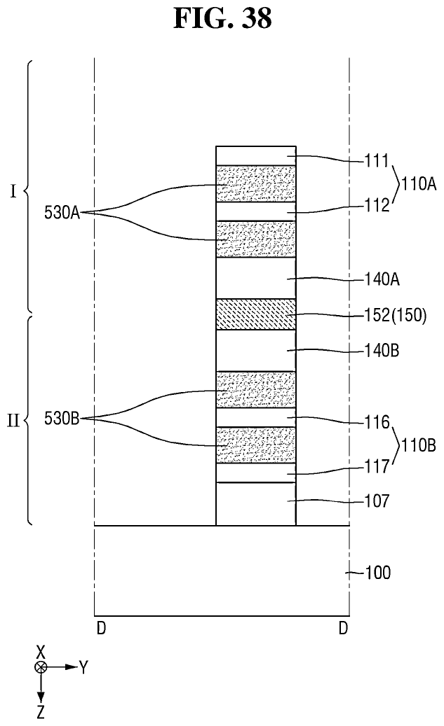

Referring to FIGS. 37 and 38, the first dummy gate structure DG1 and the second dummy gate structure DG2 are removed.

For example, the interlayer insulating film 170 that fills the space on the upper surface of the first source/drain region 160A, the outer side face of the second gate spacer 235, and the outer side face of the third gate spacer 335 may be formed. A planarization process may then be performed. The first dummy gate structure DG1 and the second dummy gate structure DG2 may then be removed. Since the first dummy gate structure DG1 and the second dummy gate structure DG2 may have an etching selectivity with respect to the first active pattern 110A and the second active pattern 110B, they may be selectively removed.

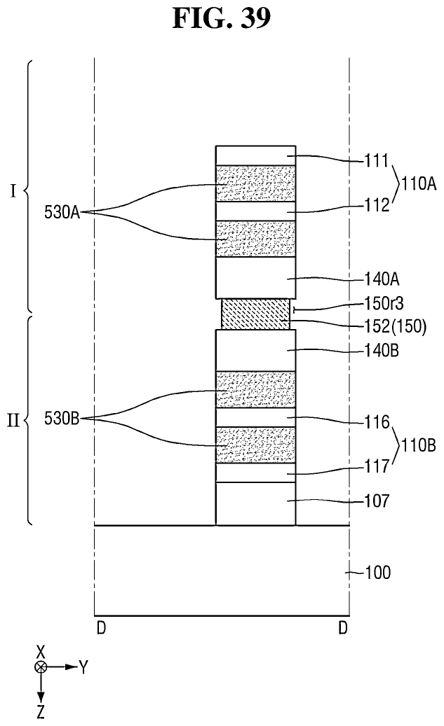

Referring to FIG. 39, a recess process is performed on the intermediate connecting layer 150.

As the first dummy gate structure DG1 and the second dummy gate structure DG2 are removed, a part of the side face of the intermediate connecting layer 150 intersecting the second direction Y may be exposed. As the recess process is performed, the side face of the intermediate connecting layer 150 intersecting the second direction Y may be recessed to form a third central recess 150r3.

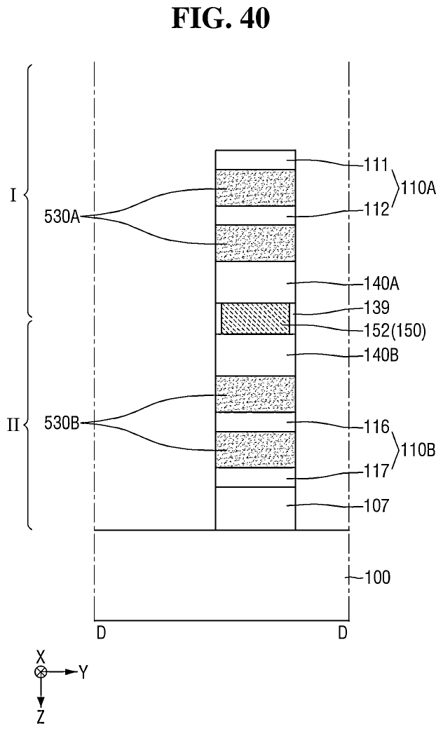

Referring to FIG. 40, the intermediate spacer 139 is formed.

The intermediate spacer 139 may be formed on the side face of the intermediate connecting layer 150 intersecting the second direction Y. For example, the intermediate spacer 139 may fill the third central recess 150r3.

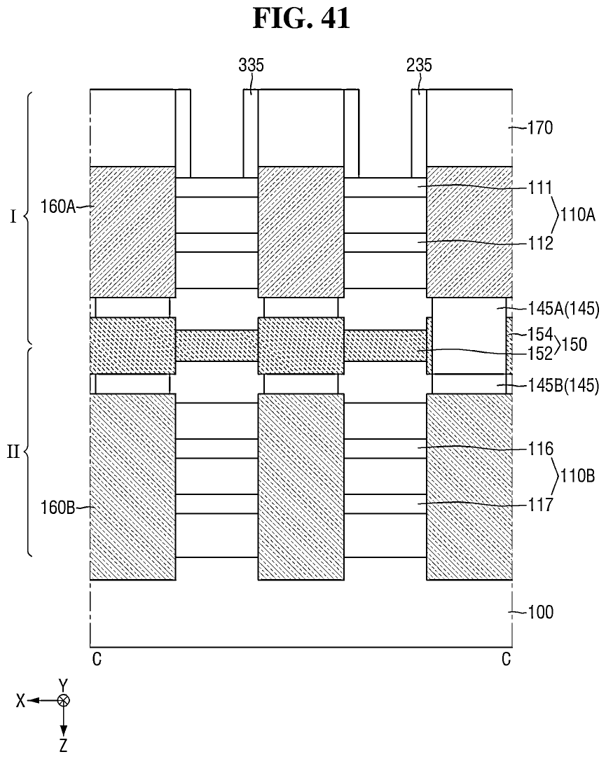

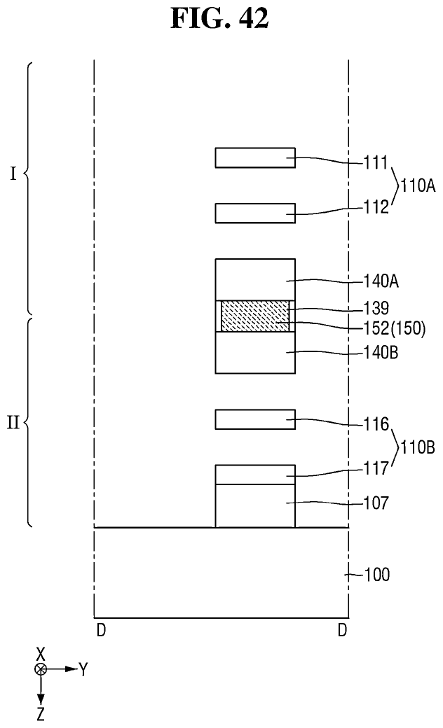

Referring to FIGS. 41 and 42, the first sacrificial pattern 530A and the second sacrificial pattern 530B are formed.

Since the first sacrificial pattern 530A and the second sacrificial pattern 530B may have an etching selectivity with respect to the first active pattern 110A and the second active pattern 110B, they may be selectively removed.

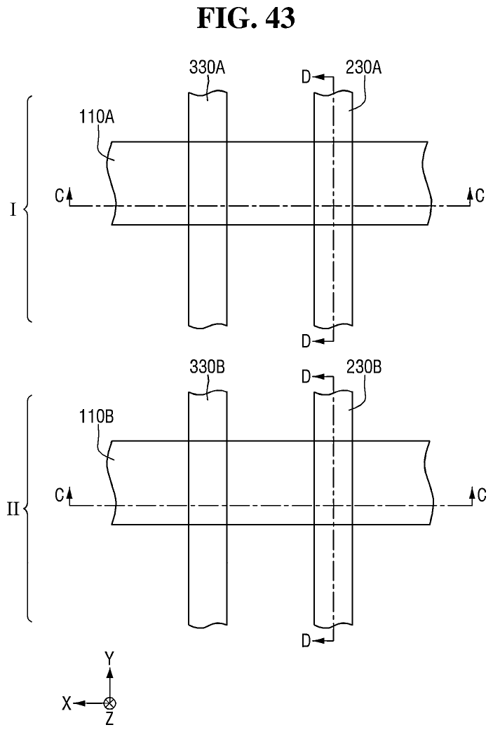

Referring to FIGS. 43 to 45, the second gate dielectric film 220, the second gate structures 230A and 230B, the second gate capping pattern 237, the third gate dielectric film 320, the third gate structures 330A and 330B, and the third gate capping pattern 337 are formed.

The second gate dielectric film 220 and the third gate dielectric film 320 may be sequentially stacked on the first active pattern 110A and the second active pattern 110B. The second gate structures 230A and 230B may be sequentially stacked on the second gate dielectric film 220, and the third gate structures 330A and 330B may be sequentially stacked on the third gate dielectric film 320. The second gate capping pattern 237 and the third gate capping pattern 337 may be formed after an etched back process is performed on the second gate structures 230A and 230B and the third gate structures 330A and 330B.

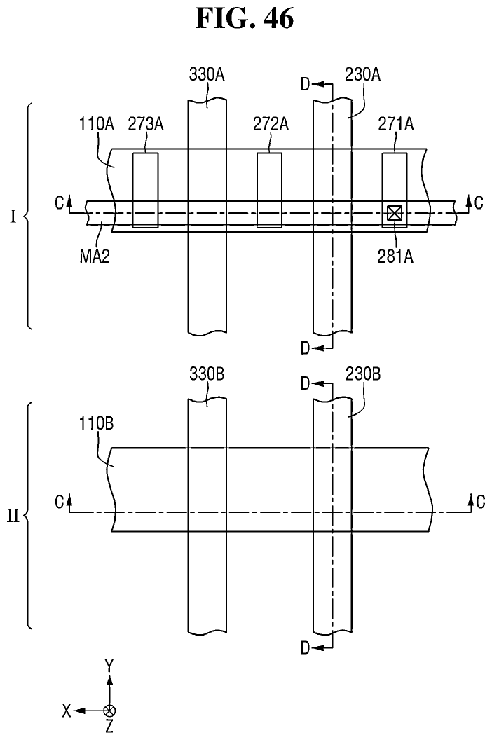

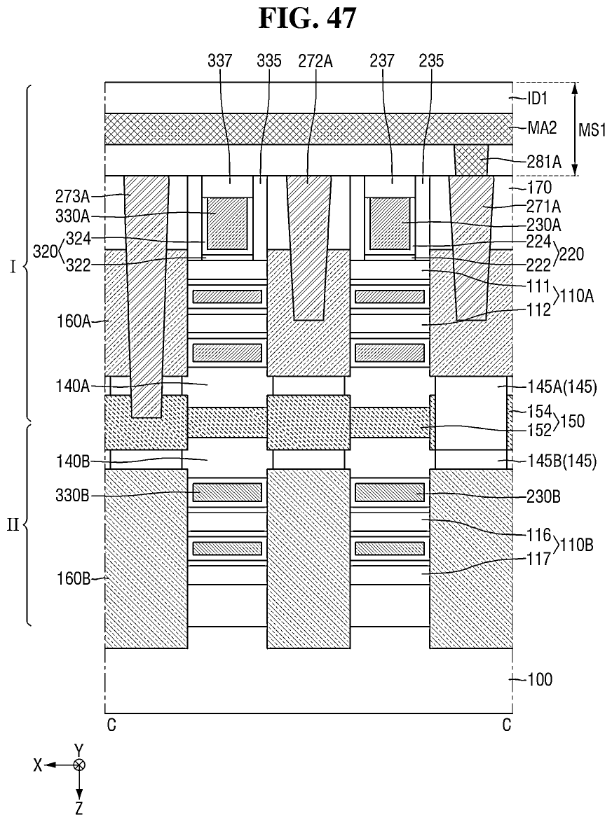

Referring to FIGS. 46 and 47, the third source/drain contacts 271A to 273A and the first wiring structure MS1 are formed.

The third source/drain contacts 271A to 273A may each be connected to the first source/drain region 160A. The first wiring structure MS1 may be stacked on the interlayer insulating film 170 and the third source/drain contacts 271A to 273A.

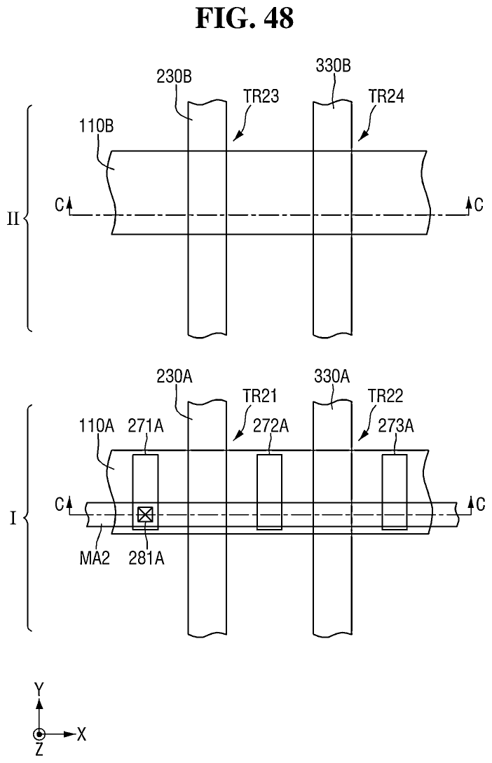

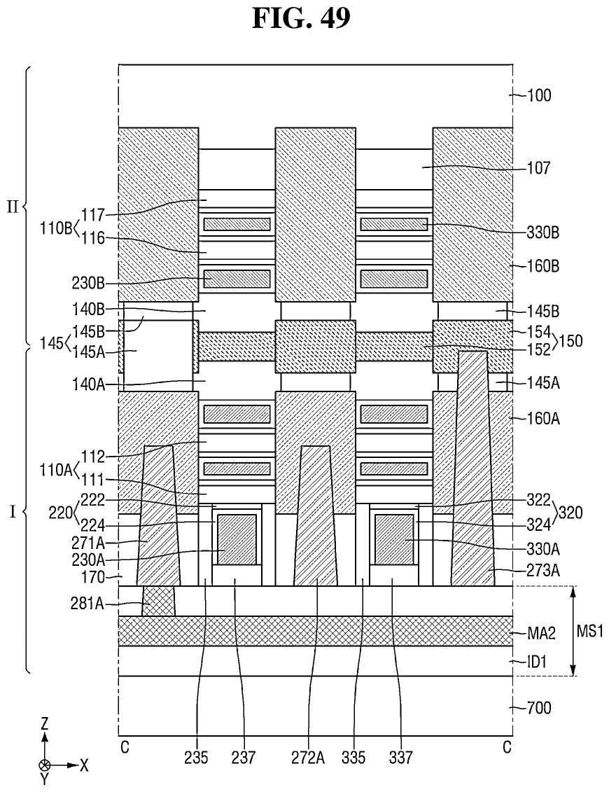

Referring to FIGS. 48 and 49, the first wiring structure MS1 is mounted on a carrier substrate 700.

For example, the carrier substrate 700 may be mounted on the resulting product of FIGS. 46 and 47. After the carrier substrate 700 is mounted, the resulting product of FIGS. 46 and 47 may be reversed.

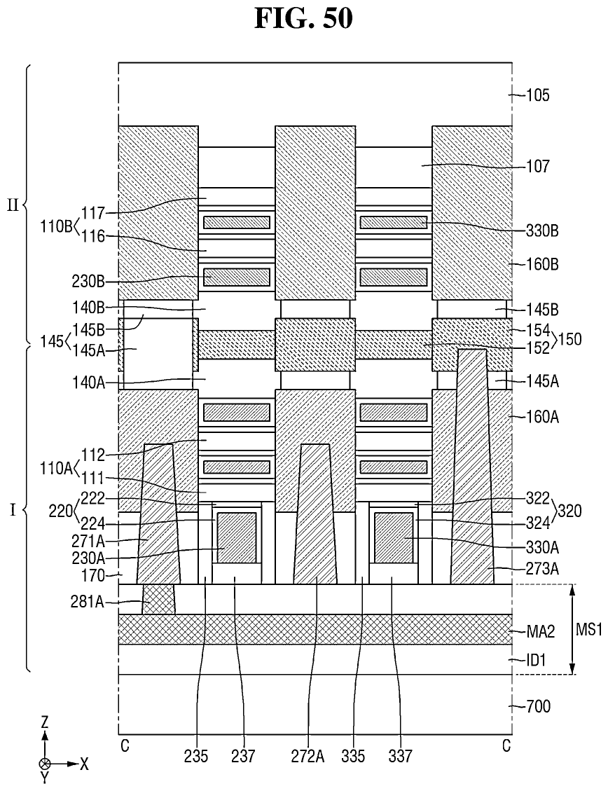

Referring to FIG. 50, the insulating substrate 105 is formed on the second source/drain region 160B and the base insulating pattern 107.

For example, at least a part of the base substrate 100 may be removed. The insulating substrate 105 that replaces the region in which the base substrate 100 is removed may then be formed.

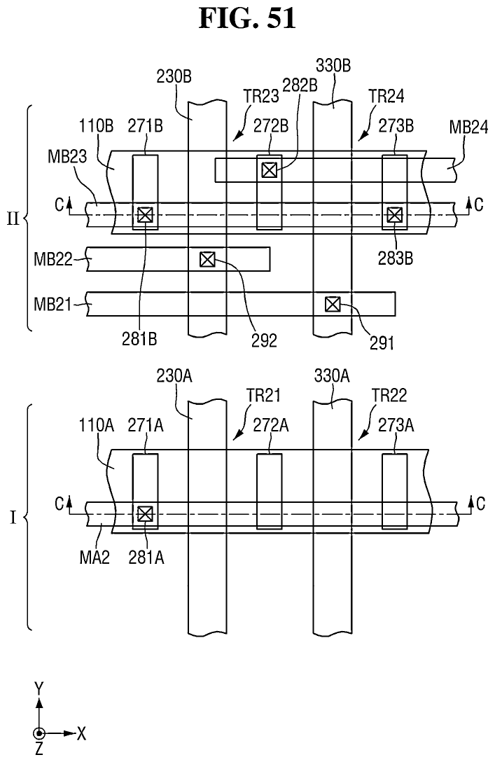

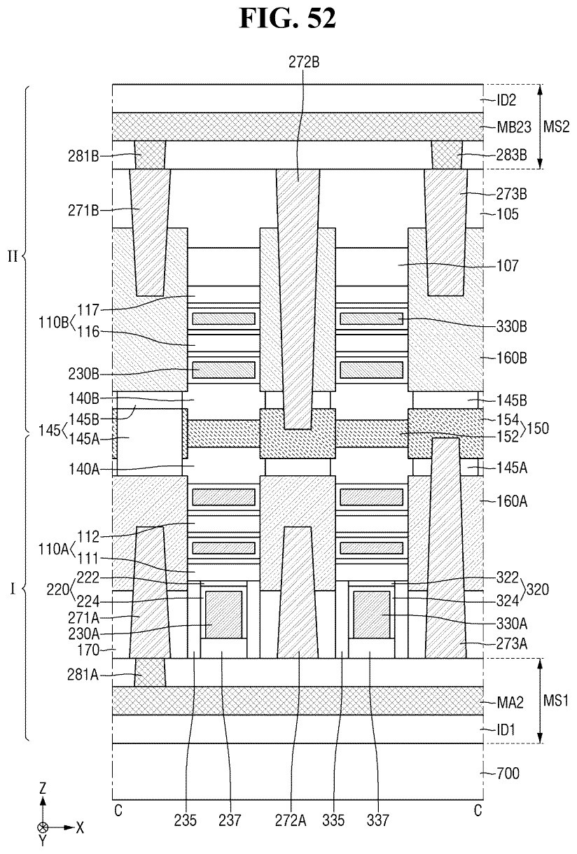

Referring to FIGS. 51 and 52, the fourth source/drain contacts 271B to 273B and the second wiring structure MS2 are formed.

The fourth source/drain contacts 271B to 273B may each be connected to the second source/drain region 160B. The second wiring structure MS2 may be stacked on the insulating substrate 105 and the fourth source/drain contacts 271B to 273B.

Next, referring to FIG. 11, the carrier substrate 700 may be removed. Accordingly, the semiconductor device explained above using FIGS. 9 to 12 may be fabricated.

In concluding the detailed description, those of ordinary skill in the art will appreciate that many variations and modifications may be made to the preferred embodiments without substantially departing from the principles of inventive concepts. Therefore, disclosed example embodiments of inventive concepts are used in a generic and descriptive sense only and not for purposes of limitation. Additionally example embodiments are not necessarily mutually exclusive with one another. For example, some example embodiments may include one or more features described with reference to one or more figures, and may also include one or more features described with reference to one or more other figures.

What is claimed is:

1. A semiconductor device comprising:
a first active pattern extending in a first direction;
a second active pattern on the first active pattern and extending in the first direction;
a gate structure on the first active pattern and the second active pattern and extending in a second direction intersecting the first direction;
a first source/drain region on side faces of the gate structure and connected to the first active pattern;
a second source/drain region on the side faces of the gate structure and connected to the second active pattern; and
an intermediate connecting layer which includes a first intermediate conductive pattern between the first active pattern and the second active pattern, and a second intermediate conductive pattern connected to the first intermediate conductive pattern between the first source/drain region and the second source/drain region.

2. The semiconductor device of claim 1, wherein
the first intermediate conductive pattern is spaced apart from the first active pattern and the second active pattern, and
the second intermediate conductive pattern is spaced apart from the first source/drain region and the second source/drain region.

3. The semiconductor device of claim 1, wherein
the first source/drain region and the second source/drain region have different conductivity types from each other.

4. The semiconductor device of claim 1, wherein
an upper surface of the second intermediate conductive pattern has a step difference from an upper surface of the first intermediate conductive pattern.

5. The semiconductor device of claim 4, wherein
the upper surface of the second intermediate conductive pattern is higher than the upper surface of the first intermediate conductive pattern.

6. The semiconductor device of claim 1, wherein
a lower surface of the second intermediate conductive pattern has a step difference from a lower surface of the first intermediate conductive pattern.

7. The semiconductor device of claim 6, wherein
the lower surface of the second intermediate conductive pattern is lower than the lower surface of the first intermediate conductive pattern.

8. The semiconductor device of claim 1, further comprising:
a first source/drain contact which penetrates the first source/drain region and is connected to the second intermediate conductive pattern.

9. The semiconductor device of claim 8, further comprising:
a second source/drain contact which penetrates the second source/drain region and is connected to the second intermediate conductive pattern.

10. The semiconductor device of claim 1,
wherein the first intermediate conductive pattern and the second intermediate conductive pattern each include an epitaxial layer having an impurity.

11. A semiconductor device comprising:
a first active pattern extending in a first direction;
a second active pattern on the first active pattern and extending in the first direction;
a gate structure on the first active pattern and the second active pattern and extending in a second direction intersecting the first direction;
a first source/drain region on side faces of the gate structure and connected to the first active pattern;
a second source/drain region on side faces of the gate structure and connected to the second active pattern;
an intermediate connecting layer interposed between the first active pattern and the second active pattern, and between the first source/drain region and the second source/drain region;
a first source/drain contact which connects the first source/drain region and the intermediate connecting layer; and
a second source/drain contact which connects the second source/drain region and the intermediate connecting layer.

12. The semiconductor device of claim 11, wherein
the first source/drain region and the second source/drain region have conductivity types different from each other.

13. The semiconductor device of claim 11, wherein
the intermediate connecting layer includes an epitaxial layer having an impurity.

14. The semiconductor device of claim 11, wherein
the first source/drain contact penetrates the first source/drain region and is connected to the intermediate connecting layer.

15. The semiconductor device of claim 14, wherein
the second source/drain contact penetrates the second source/drain region and is connected to the intermediate connecting layer.

16. A semiconductor device comprising:
a first active pattern extending in a first direction;
a second active pattern on the first active pattern and extending in the first direction;
a gate structure on the first active pattern and the second active pattern and extending in a second direction intersecting the first direction;
a first source/drain region on side faces of the gate structure and connected to the first active pattern;
a second source/drain region on side faces of the gate structure and connected to the second active pattern;
an intermediate connecting layer extending in the first direction between the first active pattern and the second active pattern, and between the first source/drain region and the second source/drain region;
a first insulating pattern interposed between the first active pattern and the intermediate connecting layer;
a second insulating pattern interposed between the second active pattern and the intermediate connecting layer;
a first intermediate insulating layer interposed between the first source/drain region and the intermediate connecting layer; and
a second intermediate insulating layer interposed between the second source/drain region and the intermediate connecting layer.

17. The semiconductor device of claim 16, further comprising:
an intermediate spacer between the gate structure and the intermediate connecting layer and extending along side faces of the intermediate connecting layer.

18. The semiconductor device of claim 16, wherein
a part of the first intermediate insulating layer cuts a part of the intermediate connecting layer.

19. The semiconductor device of claim 16, wherein
the uppermost face of the first source/drain region is higher than the lowermost face of the first insulating pattern.

20. The semiconductor device of claim 16, wherein
the lowermost face of the second source/drain region is lower than the uppermost face of the second insulating pattern.
